(19) United States
(12) Patent Application Publication
(10) Pub. No.: US 2026/0033091 A1
(43) Pub. Date: Jan. 29, 2026

(54) DISPLAY DEVICE

(71) Applicant: LG Display Co., Ltd., Seoul (KR)

(72) Inventors: Dae Han WON, Paju-si (KR); Jae Kwang LEE, Paju-si (KR); Hae Sung LEE, Paju-si (KR); Jae Yong YUN, Paju-si (KR)

(73) Assignee: LG Display Co., Ltd., Seoul (KR)

(21) Appl. No.: 19/239,351

(22) Filed: Jun. 16, 2025

(30) Foreign Application Priority Data
Jul. 25, 2024 (KR) 10-2024-0098668

(51) Int. Cl. H10H 29/80; G09G 3/32; H10H 29/37; H10H 29/855

(52) U.S. Cl. CPC H10H 29/8321; H10H 29/37; H10H 29/8323; H10H 29/8552; G09G 3/32; G09G 2300/0861

(57) ABSTRACT

The disclosure discloses a display device including a substrate, a circuit layer disposed on the substrate, and a plurality of banks disposed on the circuit layer. A plurality of light-emitting elements is disposed on the banks, each having a first electrode and a second electrode. A contact electrode is disposed on the bank and is electrically connected to the first electrode. The contact electrode includes a contact opening. An optical layer covers side surfaces of the plurality of light-emitting elements and the contact electrode, and includes a contact hole aligned with the contact opening of the contact electrode. The contact electrode is electrically connected with the second electrode through the contact hole of the optical layer. A transparent conductive layer is not present in the region of electrical connection between the contact electrode and the second electrode. This structure improves adhesion and maintains the structural integrity of the optical layer.

### CROSS-REFERENCE TO RELATED APPLICATION

This application claims priority to and the benefit of Korean Patent Application No. 2024-0098668, filed in the Republic of Korea on Jul. 25, 2024, the entire disclosure of which is incorporated herein by reference for all purposes, as if fully set forth herein.

### BACKGROUND

### Technical Field

The present specification relates to a display device, and particularly to, for example, without limitation, a display device capable of suppressing delamination of an optical layer disposed therein.

### Description of Related Art

Examples of a display device include organic light-emitting diode (OLED) display devices that emit light by itself, liquid crystal display (LCD) devices that require separate light sources, etc.

Recently, display devices including light-emitting diodes (LEDs) have been attracting attention as next-generation display devices. Since an LED is formed of an inorganic material rather than an organic material, the display devices including the LEDs have a faster turn-on speed, better luminous efficiency, and higher luminance images than LCD devices or OLED display devices.

The description provided in the background section should not be assumed to be prior art merely because it is mentioned in or associated with the background section. The background section may include information that describes one or more aspects of the subject technology.

### BRIEF SUMMARY

The disclosure relates to a display device with improved structural reliability, particularly addressing issues of delamination between the optical layer and the contact electrodes. This is achieved by removing or omitting the transparent conductive layer from the uppermost surface of the contact electrode in the area of the contact hole. This configuration enhances adhesion between the layers, reduces the risk of cracking in the cathode electrode, and increases the margin for forming openings in insulating layers, thereby improving alignment accuracy and overall manufacturing yield.

Additional features include the use of banks with varying sizes to support proper contact formation, the application of flexible conductive patterns in the bending regions to prevent cracking of the link wires, and the incorporation of redundant micro light emitting elements within each pixel to compensate for potential defects during the transfer process. These design choices contribute to enhanced mechanical durability, electrical stability, and production efficiency, particularly in high-resolution and flexible display devices.

One or more aspects of embodiments of the present specification are to provide a display device in which an area of a transparent conductive layer of an uppermost layer of a contact electrode in a contact hole area is removed to form an interface between an optical layer and the contact electrode so that delamination of the optical layer is suppressed and the crack prevention effect is expected in a cathode electrode.

Aspects of embodiments of the present specification are not limited to the above-described aspect, and other aspects that are not mentioned will be able to be clearly understood by those skilled in the art from the following description.

According to an embodiment of the present specification, to achieve these and other aspects of the inventive concepts, as embodied and broadly described herein, there is provided a display device including a plurality of banks disposed on a substrate, a plurality of light-emitting elements disposed on the banks and each connected with a first electrode and a second electrode, a contact electrode disposed on the bank to be electrically connected with the second electrode and having a contact opening, and an optical layer covering side surfaces of the plurality of light-emitting elements and the contact electrode and having a contact hole located in the contact opening of the contact electrode, wherein the contact electrode is electrically connected with the second electrode through the contact hole of the optical layer without a transparent conductive layer.

According to another aspect of the present disclosure, there is provided a display device including a plurality of banks disposed on a substrate; a plurality of light-emitting elements disposed on the banks and each connected with a first electrode and a second electrode; a contact electrode disposed to be electrically connected with the second electrode and having a contact opening; and an optical layer covering side surfaces of the plurality of light-emitting elements and the contact electrode and having a contact hole located in the contact opening of the contact electrode, wherein the second electrode is electrically connected with the contact electrode through the contact hole of the optical layer, and the contact electrode includes a transparent conductive layer spaced apart from the contact hole.

According to another aspect of the present disclosure, there is provided a display device including a plurality of banks disposed on a substrate; a plurality of light-emitting elements disposed on the banks and each connected with a first electrode and a second electrode; a contact electrode disposed to be electrically connected with the second electrode in a contact region; and an optical layer covering side surfaces of the plurality of light-emitting elements and the contact electrode and having a contact hole located in the contact region of the contact electrode, wherein the second electrode is electrically connected with the contact electrode through the contact hole of the optical layer, and wherein an uppermost layer of the contact electrode in contact with the optical layer is not formed of a transparent conductive material.

Detailed items according to various examples of the present specification other than the above-described configuration are included in the following description and the accompanying drawings.

According to the present specification, by removing an area of a transparent conductive layer, which is an uppermost layer of a contact electrode located in an area of a contact hole for connecting a second electrode to a contact electrode, or omitting the transparent conductive layer, which is the uppermost layer of the contact electrode, to form an interface between an optical layer and the contact electrode, delamination of the optical layer is suppressed, thereby expecting the crack prevention effect in the second electrode.

According to the present specification, by removing an area of a transparent conductive layer, which is an uppermost layer of a contact electrode located in a formation area of a contact hole for connecting a second electrode to the contact electrode, to form an contact opening or omitting the transparent conductive layer, which is the uppermost layer of the contact electrode, so as not to form a separate contact opening, a formation margin of an opening of an insulating layer above the contact electrode is secured, thereby improving misalignment.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features, and advantages of the present disclosure will become more apparent to those of ordinary skill in the art by describing exemplary embodiments thereof in detail with reference to the accompanying drawings, in which:

FIG. 1 is an exploded perspective view of a display device according to an example embodiment of the present disclosure;

FIG. 2 is a plan view of a display device according to an example embodiment of the present disclosure;

FIG. 3 is an enlarged plan view of a connection structure of a display device according to an example embodiment of the present disclosure;

FIG. 4 is a diagram illustrating a circuit structure according to an example embodiment of the present disclosure.

FIG. 5 is a plan view of a display device according to an example embodiment of the present disclosure;

FIG. 6 is a plan view of a display device according to an example embodiment of the present disclosure.

FIG. 7 is an enlarged view of a display device according to an example embodiment of the present disclosure.

FIG. 8 is a cross-sectional view of a display device according to an example embodiment of the present disclosure.

FIG. 9 is an enlarged cross-sectional view of a display device according to an example embodiment of the present disclosure.

FIG. 10 is an example of a cross-sectional view taken along the line II-II′ of FIG. 7.

FIG. 11 is an example of an enlarged plan view of part A in FIG. 10;

FIG. 12 is an example of a cross-sectional view taken along line III-III′ in FIG. 11;

FIG. 13 is a cross-sectional view taken along line II-II′ of FIG. 7, illustrating a cross-sectional view of a display device according to another example embodiment of the present disclosure.

FIG. 14 is an example of an enlarged plan view of part B in FIG. 14;

FIG. 15 is an example of a cross-sectional view taken along line IV-IV′ in FIG. 14; and

FIGS. 16 to 19 are views illustrating devices to which the display devices according to the example embodiments of the present disclosure are applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

The advantages and features of the present disclosure, and methods of achieving them will become apparent upon reference to the example embodiments described in detail below in conjunction with the accompanying drawings. However, the present disclosure is not limited to the following example embodiments disclosed herein, but may be implemented in various different forms; rather, example embodiments are provided to make the disclosure of the present disclosure complete and to enable those skilled in the art to fully comprehend the scope of the present disclosure. Any implementation described herein as an “example” is not necessarily to be construed as preferred or advantageous over other implementations.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Identical reference numerals may designate identical components throughout the description. Further, in describing the present disclosure, detailed descriptions of related known technologies may be omitted so as not to obscure the essence of the present disclosure. Terms such as, “including,” “having,” or “comprising” as used herein are generally intended to allow for the addition of other components, unless the terms are used with a more limiting term such as “only.” An element described in the singular form is intended to include a plurality of elements, and vice versa, unless the context clearly indicates otherwise.

In the interpretation of components, they are construed to include ordinary error range or tolerance range even if there is no explicit description of such an error or tolerance range.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “following,” “subsequent,” “next,” and “before,” a case that is not continuous may be included unless a more limiting term, such as “just,” “immediate(ly),” or “direct(ly)” is used.

The first, the second, and so on are used to describe various components, but the essence, sequence, order, or number of these components are not limited by these terms. These terms are used only to distinguish one component from another. For example, a first component could be termed a second component, and, similarly, a second component could be termed a first component, without departing from the scope of the present disclosure.

Terms such as first, second, A, B, (a), or (b) may be used to describe elements of the present disclosure. Such terms are intended only to distinguish one component from another and are not intended to define the nature, sequence, order, or number of such components.

When a component is described as being “connected,” “coupled,” “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component or layer is described as being “in contacted” or “overlapped” with another component or layer, it is to be understood that the component or layer may be in direct contacted or overlap with the other component or layer, but that there may also be other components or layer “interposed” between the respective components or layer which may be in direct or indirect contacted or overlap with, unless specifically stated otherwise.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms the first direction, the second direction, the third direction, the row direction, the column direction, the X-axis direction, the Y-axis direction, and the Z-axis direction are not to be interpreted solely as a geometric relationship in which the relationship to one another is perpendicular, but may refer to a broader range of orientations in which the configurations of the present disclosure may function.

Each of the features of various embodiments of the present disclosure may be coupled or combined with one another in whole or in part, and may be technologically interlocked and operated in various ways, and each of the embodiments may be carried out independently or in conjunction with one another.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

A display device according to the present disclosure may be implemented as a light emitting display device or a quantum dot display (QDD) device. Hereinafter, for convenience of description, a light emitting display device self-emitting light based on an inorganic light emitting diode or an organic light emitting diode will be described for example, but the present disclosure is not limited thereto, and other various types of display device may also be similarly applied.

In the present disclosure, a pixel circuit and a gate driver formed on a display panel may include a plurality of transistors. The transistors may be implemented with oxide thin film transistors (oxide TFTs) including an oxide semiconductor, low temperature polysilicon (LTPS) TFTs including low temperature polysilicon, and the like.

Moreover, a thin film transistor (TFT) described below may be implemented with an n-type TFT, a p-type TFT, or a combination of an n-type TFT and a p-type TFT. A TFT may be a three-electrode element including a gate, a source, and a drain. The source may be an electrode which provides a carrier to a transistor. In the TFT, a carrier may start to flow from the source. The drain may be an electrode where the carrier flows from the TFT to the outside. For example, in the TFT, the carrier flows from the source to the drain.

In the p-type TFT, because a carrier is a hole, a source voltage may be higher than a drain voltage so that the hole flows from the source to the drain. In the p-type TFT, because the hole flows from the source to the drain, a current may flow from the source to the drain. On the other hand, in the n-type TFT, because a carrier is an electron, a source voltage may be lower than a drain voltage so that the electron flows from the source to the drain. In the n-type TFT, because the electron flows from the source to the drain, a current may flow from the drain to the source. However, a source and a drain of a TFT may switch therebetween based on a voltage applied thereto. Based thereon, in the following description, one of a source and a drain will be described as a first electrode, and the other of the source and the drain will be described as a second electrode. However, since the source electrode and the drain electrode can be changed according to an applied voltage, the source electrode and the drain electrode of the transistor are not fixed.

Hereinafter, various example embodiments of the present disclosure will be described in detail with reference to the accompanying drawings. Further, all the components of each display device according to all embodiments of the present disclosure are operatively coupled and configured.

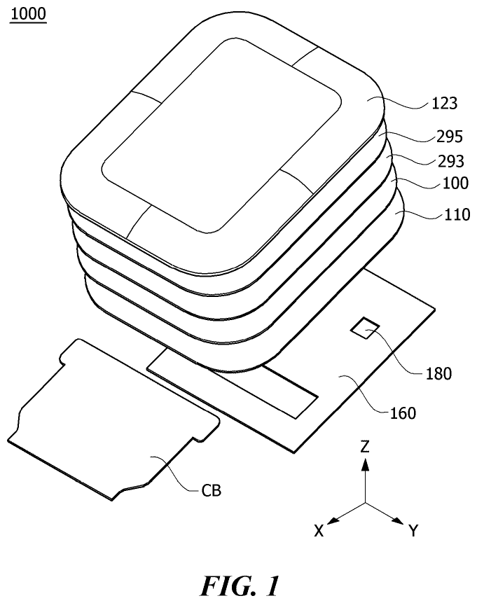

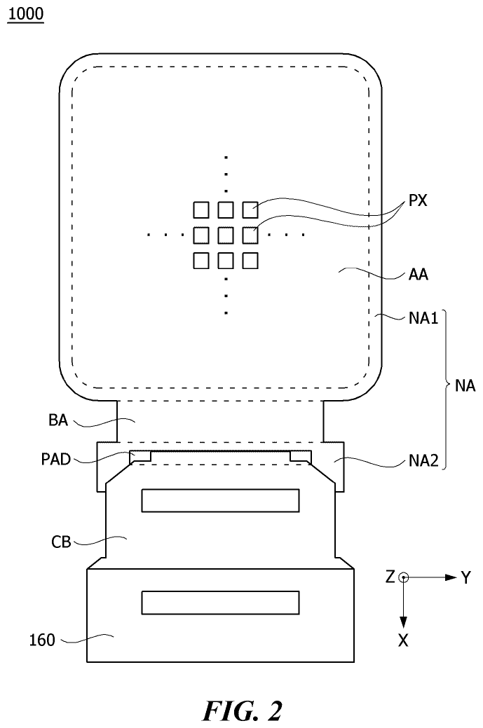

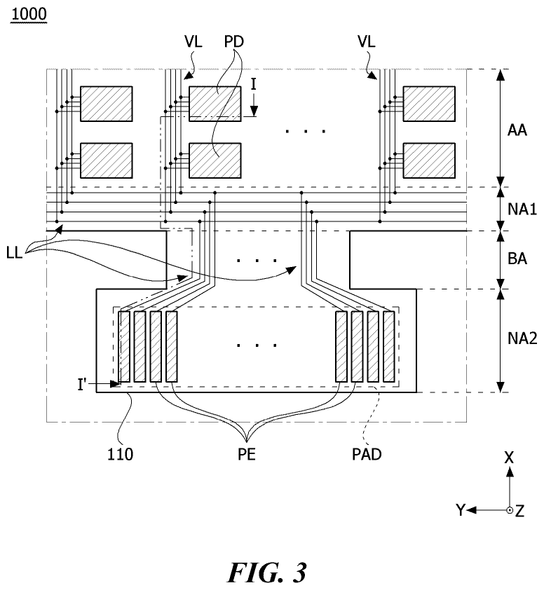

FIG. 1 is an exploded perspective view of a display device according to one embodiment of the present disclosure; FIG. 2 is a plan view of a display device according to one embodiment of the present disclosure; FIG. 3 is an enlarged plan view of a connection structure of a display device according to one embodiment of the present disclosure;

Referring to FIGS. 1 to 3, a display device 1000 according to one embodiment of the present disclosure may include one or more of a display panel 100, a polarizing layer 293, an adhesive layer 295, a cover member 120, a substrate (or support substrate) 110, a flexible circuit board CB, and a printed circuit board 160. However, the present disclosure is not limited thereto, and more or less components may be included in the display device of the present disclosure. For example, various other function layers such as a diffusion layer, a reflective layer may also be disposed on the display device 1000.

For example, the display device 1000 may include a substrate 110. The substrate 110 may be a member that supports other components of the display device 1000. The substrate 110 may be made of an insulating material. For example, the substrate 110 may be made of glass, resin, or the like. Additionally, the substrate 110 may be made of a material having flexibility. For example, the substrate 110 may be made of a flexible plastic material such as any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC), polyvinyl alcohol (PVA), polyimide (PI), and polystyrene (PS). However, the embodiments of the present disclosure are not limited thereto.

The display panel 100 may implement information, video, and/or an image provided to a user. For example, the display panel 100 may include a display area AA and a non-display area NA adjacent to the display area AA. For example, the substrate 110 may include the display area AA and the non-display area NA. The display area AA and non-display area NA are not limited to being described only with respect to the substrate 110 but may be described throughout the entire display device 1000.

The display area AA may be an area in which an image is displayed. The display area AA may include a plurality of pixels PX. Each of the plurality of pixels PX may include a plurality of sub-pixels. A plurality of micro-LEDs may be respectively arranged in the plurality of sub-pixels. The plurality of micro-LEDs may be configured differently depending on the type of display device 1000. For example, when the display device 1000 is an inorganic light emitting display device, the light emitting element may be a light-emitting diode (LED), a micro light-emitting diode (Micro-LED), or a mini-light-emitting diode (MLED), but embodiments of the present specification are not limited thereto.

The non-display area NA may be an area in which no image is displayed. Various wires and circuits for driving the plurality of pixels PX of the display area AA may be positioned in the non-display area NA. For example, in the non-display area NA, various wires and driving circuits may be mounted, and a pad portion PAD to which an integrated circuit, a printed circuit, and the like are connected may be provided, but the embodiments of the present disclosure are not limited thereto.

For example, the driving circuit may be a data driving circuit and/or a gate driving circuit, but the embodiments of the present disclosure are not limited thereto. Wires through which a control signal for controlling the driving circuits is supplied may be provided. For example, the control signal may include various timing signals including a clock signal, an input data enable signal, and synchronization signals, but the embodiments of the present disclosure are not limited thereto. The control signal may be received through the pad portion PAD. For example, link wires LL for transmitting signals may be positioned in the non-display area NA. For example, the pad portion PAD may be connected to driving components such as the flexible circuit board CB and the printed circuit board 160.

According to the present disclosure, the non-display area NA may include a first non-display area NA1, a bending area BA, and a second non-display area NA2. For example, the first non-display area NA1 may be an area that surrounds at least a portion of the display area AA. The bending area BA may be an area extending from at least one of the plurality of sides of the first non-display area NA1, and may be a bendable area. The second non-display area NA2 may be an area extending from the bending area BA, and the pad portion PAD may be positioned in the second non-display area NA2. For example, the bending area BA may be in a bent state, and the remaining area of the substrate 110, excluding the bending area BA, may be in a flat state. In this case, as the bending area BA is in a bent state, the second non-display area NA2 may be positioned on the rear surface of the display area AA. However, the embodiments of the present disclosure are not limited thereto.

The display area AA of the substrate 110 or the display device 1000 may be configured in various shapes depending on the design of the display device 1000. For example, the display area AA may be configured in a rectangular shape with four rounded corners, but the embodiments of the present disclosure are not limited thereto. In another example, the display area AA may be configured in a rectangular shape with four right-angled corners, a circular shape, or the like, but the embodiments of the present disclosure are not limited thereto.

According to the present disclosure, the width of the second non-display area NA2 in which a plurality of pad electrodes PE are arranged may be greater than the width of the bending area BA in which only the plurality of link wires LL are arranged. Additionally, the width of the display area AA in which the plurality of sub-pixels are arranged may be greater than the width of the bending area BA in which only the plurality of link wires LL are arranged. In the drawings, the width of the bending area BA is illustrated as being smaller than that of other areas of the substrate 110. However, the shape of the substrate 110 including the bending area BA is merely exemplary, and the embodiments of the present disclosure are not limited thereto.

Referring to FIG. 2, in the display device according to an exemplary configuration of the present specification, a display area AA in which a plurality of pixels PX are disposed and a first non-display area NA1 surrounding the display area AA may be disposed.

Referring to FIG. 3, a plurality of pixel driving circuits PD may be arranged in the display area AA. The plurality of pixel driving circuits PD may be circuits for driving the micro-LEDs of the plurality of sub-pixels. Each of the plurality of pixel driving circuits PD may include a plurality of transistors including a driving transistor, a storage capacitor, and the like and may supply a control signal, power, and a driving current to the micro-LEDs of the plurality of sub-pixel to control the light emission operation of the plurality of micro-LEDs. For example, the pixel driving circuit PD may include a power wire and a signal wire for controlling the on/off state and/or light emission time of the micro-LED. For example, the plurality of pixel driving circuits PD may be a driver (or driving component) manufactured using a metal-oxide-silicon field effect transistor (MOSFET) fabrication process on a semiconductor substrate, but the embodiments of the present disclosure are not limited thereto. The driver may include the plurality of pixel driving circuits PD and may drive the plurality of sub-pixels.

Referring also to FIG. 1, the flexible circuit board (also referred to as flexible printed circuit or flexible film) CB and the printed circuit board 160 may be positioned below the display panel 100. The flexible circuit board CB and the printed circuit board 160 may be positioned on at least one edge of the display panel 100, but the embodiments of the present disclosure are not limited thereto.

One side of the flexible circuit board CB may be attached to the display panel 100, and the other side thereof may be attached to the printed circuit board 160, but embodiments of the present disclosure are not limited thereto. The flexible circuit board CB may be a flexible film, but embodiments of the present disclosure are not limited thereto.

The pad portion PAD including the plurality of pad electrodes PE may be positioned in the second non-display area NA2. Driving components, including one or more flexible circuit boards (or flexible films) CB and the printed circuit board 160, may be attached or bonded to the pad portion PAD. The plurality of pad electrodes PE of the pad portion PAD may be electrically connected to the one or more flexible circuit boards (or flexible films) CB, and may transmit various signals (or power) from the printed circuit board 160 and the flexible circuit board (or flexible film) CB to the plurality of pixel driving circuits PD of display area AA.

The flexible circuit board (or flexible film) CB may be a film in which various components are arranged on a base film having flexibility. For example, a driving IC, such as a gate driver IC or a data driver IC, may be positioned on the flexible circuit board (or flexible film) CB, but the embodiments of the present disclosure are not limited thereto.

The driving IC may be a component that processes data and a driving signal for displaying an image. The driving IC may be disposed by a method such as a chip-on-glass (COG) method, a chip-on-film (COF) method, or a tape carrier package (TCP) method depending on a method of being mounted, but embodiments of the present disclosure are not limited thereto. The flexible circuit board (or flexible film) CB may be attached to or bonded on the plurality of pad electrodes PE through a conductive adhesive layer, but embodiments of the present disclosure are not limited thereto.

The printed circuit board 160 may be a component electrically connected to one or more flexible circuit boards (or flexible films) CB and supplying signals to the driving IC. The printed circuit board 160 may be disposed at one side of the flexible circuit board (or flexible film) CB and electrically connected to the flexible circuit board (or flexible film) CB. Various components for supplying various signals to the driving IC may be disposed on the printed circuit board 160. For example, various components, such as a timing controller, a power supply unit, a memory, a processor, etc., may be disposed on the printed circuit board 160. For example, the printed circuit board 160 may include a power management integrated circuit (PMIC), but embodiments of the present disclosure are not limited thereto.

The printed circuit board 160 may include at least one hole 180, but the embodiments of the present disclosure are not limited thereto. An internal component for sensing ambient light, temperature, or the like, which may be provided to a plurality of sensors, may be positioned in a region corresponding to the at least one hole 180. For example, the internal component may include an ambient light sensor (ALS), a temperature sensor, or the like, but the embodiments of the present disclosure are not limited thereto. For example, the hole 180 may be a transmission hole or the like, but the embodiments of the present disclosure are not limited thereto. In another example, the hole 180 may be a transmission region or hole, but the example embodiments of the present disclosure are not limited thereto.

Referring to FIG. 1, the polarizing layer 293 may be positioned on the display panel 100. The polarizing layer 293 may prevent or reduce light generated from an external light source from entering the interior of the display panel 100 and affecting the micro-LEDs or the like.

The cover member 120 may be positioned on the polarizing layer 293. The cover member 120 may be a member for protecting the display panel 100. The adhesive layer 295 may be positioned between the polarizing layer 293 and the cover member 120. The cover member 120 may be attached to the display panel 100 by using the adhesive layer 295. The adhesive layer 295 may include an optically clear adhesive (OCA), an optically clear resin (OCR), a pressure sensitive adhesive (PSA), or the like, but the embodiments of the present disclosure are not limited thereto.

The substrate 110 may be positioned between the display panel 100 and the printed circuit board 160. The substrate 110 may reinforce the rigidity of the display panel 100. The substrate 110 may be a back plate, but the embodiments of the present disclosure are not limited thereto.

Referring to FIGS. 1 to 3, the plurality of link wires LL may be arranged in the first and second non-display areas NA1 and NA2. The plurality of link wires LL may be wires for transmitting various signals from the one or more flexible circuit boards (or flexible films) CB and the printed circuit board 160 to the display area AA. The plurality of link wires LL may extend from the plurality of pad electrodes PE of the second non-display area NA2 toward the bending area BA and the first non-display area NA1, and may be electrically connected to a plurality of driving wires VL of the display area AA.

The plurality of pixel driving circuits PD may be driven by receiving signals from one or more flexible circuit boards (or flexible films) CB and the printed circuit board 160 through the driving wiring VL in the display area AA and the link wiring LL in the non-display area NA.

For example, a plurality of driving wires VL may be wires for transmitting a signal output from the flexible circuit board (or flexible film) CB and the printed circuit board 160 together with a plurality of link wires LL to a plurality of pixel driving circuits PD. A plurality of driving wires VL may be disposed in the display area AA and electrically connected to each of a plurality of pixel driving circuits PD. A plurality of driving wires VL may extend from the display area AA toward the non-display area NA and may be electrically connected to a plurality of link wires LL.

Therefore, the signal output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, a portion of the plurality of link wires LL may also be bent together. Stress may be concentrated on a portion of the bent link wires LL, thereby causing cracks in the link wires LL. Accordingly, the plurality of link wires LL may be formed of a highly flexible conductive material to reduce cracks when the bending area BA is bent. For example, the plurality of link wires LL may be formed of a highly flexible conductive material, such as gold (Au), silver (Ag), or aluminum (Al), but the embodiments of the present disclosure are not limited thereto.

Additionally, the plurality of link wires LL may be formed of one of various conductive materials used in the display area AA. For example, the plurality of link wires LL may be made of molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto. The plurality of link wires LL may have a multilayer structure made of various conductive materials. For example, the plurality of link wires LL may have a triple-layer structure of titanium (Ti)/aluminum (Al)/titanium (Ti), but the embodiments of the present disclosure are not limited thereto.

A plurality of link wirings LL may be configured in various shapes to reduce stress. At least a portion of the plurality of link wirings LL disposed on the bending area BA may extend in the same direction as the extending direction of the bending area BA, or may extend in a direction different from the extending direction of the bending area BA to reduce stress. For example, when the bending area BA extends in one direction from the first non-display area NA1 to the second non-display area NA2, at least a portion of the link wiring LL disposed on the bending area BA may extend in a direction inclined to the one direction.

For another example, at least a portion of the plurality of link lines LL may be configured in various shapes. For example, at least a portion of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal shape, a circular shape, and an omega (Q) shape is repeatedly arranged, but embodiments of the present disclosure are not limited thereto.

Therefore, in order to minimize or reduce the stress concentrated on the plurality of link lines LL and the corresponding crack, the shape of the plurality of link lines LL may be formed in various shapes including the above-described shape, but embodiments of the present disclosure are not limited thereto.

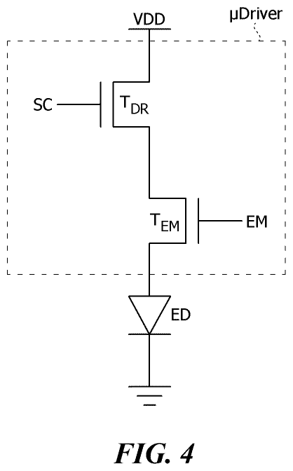

FIG. 4 is a diagram illustrating a circuit structure according to an embodiment of the present disclosure.

Although FIG. 4 illustrates that one light emitting element ED is connected to the micro-driver, the present disclosure is not limited thereto. For example, eight light emitting elements ED may be connected to one micro-driver. For another example, 16 light emitting elements ED may be connected to one micro-driver, 32 light emitting elements ED or 64 light emitting elements ED may be connected to one micro-driver at the same time. The light emitting element ED may be a micro-light emitting element LED. The micro driver μDriver may correspond to the pixel driving circuit PD or may include a plurality of pixel driving circuits PD integrated therein.

In one micro driver μDriver may include a driving transistor T_{DR} and a light emitting transistor T_{EM}, but embodiments of the present disclosure are not limited thereto. For example, one or more other transistors and one or more capacitors may be included in the micro driver μDriver. For example, 2T1C, 3T1C, 4T1C, 5T1C, 3T2C, 4T2C, 5T2C, 6T2C, 7T1C, 7T2C, 8T1C, 8T2C structures, etc., are also possible for the micro driver μDriver. For example, in the driving transistor T_{DR}, a high potential power voltage VDD may be applied to the first electrode, a first electrode of the light emitting transistor T_{EM} may be connected to the second electrode, and a scan signal SC may be applied to the gate electrode. The scan signal SC applied to the gate electrode of the driving transistor T_{DR} is a direct current power source, and a fixed reference voltage Vref may be applied to each frame, but embodiments of the present disclosure are not limited thereto.

In the light emitting transistor T_{EM}, the second electrode of the driving transistor T_{DR} is connected to the first electrode, the light emitting element ED is connected to the second electrode, and the light emitting signal EM may be applied to the gate electrode. The light emitting signal EM applied to the gate electrode of the light emitting transistor T_{EM} may be a pulse width modulation signal that changes every frame, but embodiments of the present disclosure are not limited thereto.

In the light emitting element ED, the first electrode may be connected to the second electrode of the light emitting transistor T_{EM}, and the second electrode may be connected to the ground. For example, the first electrode may be an anode electrode and the second electrode may be a cathode electrode, but configurations of the present disclosure are not limited thereto. Each of the driving transistor T_{DR} and the light emitting transistor T_{EM} may be an n-type transistor or a p-type transistor.

In the micro driver μDR, the driving transistor T_{DR} may be turned on by the scan signal SC applied from the timing controller T-CON, and the light emitting transistor T_{EM} may be turned on by the light emitting signal EM. As a result, the driving current is applied to the light emitting element ED via the driving transistor T_{DR} and the light emitting transistor T_{EM} by the high potential power voltage VDD applied to the first electrode of the driving transistor T_{DR}, and thus the light emitting element ED may emit light.

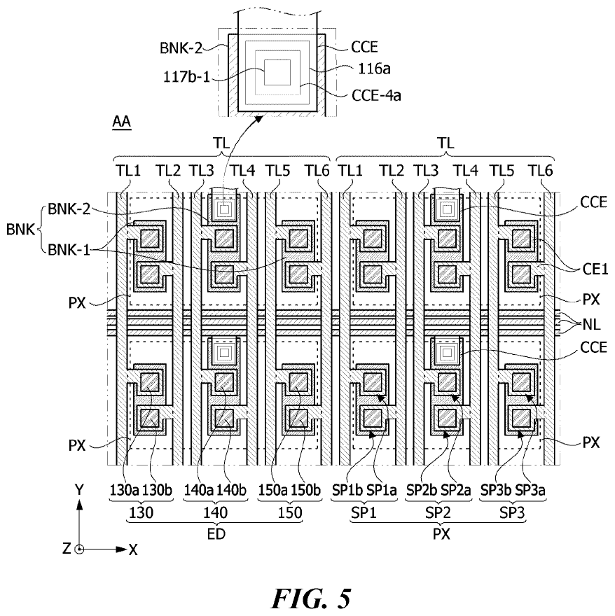

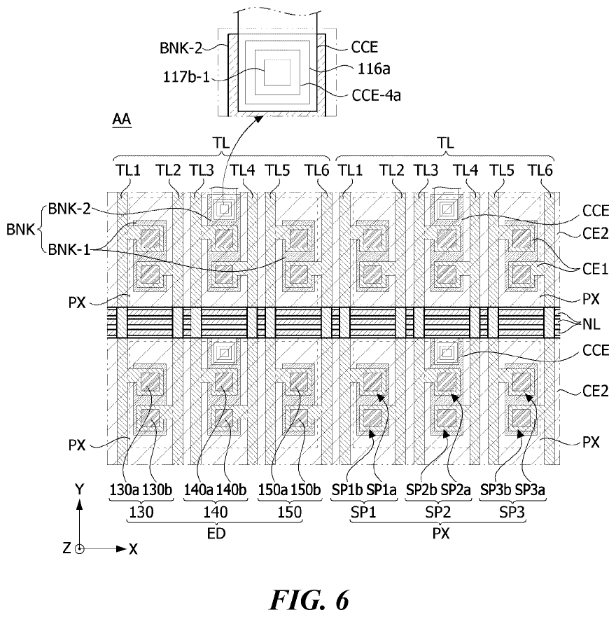

FIGS. 5 to 7 are plan views of a display device according to an embodiment of the present disclosure. For example, FIG. 5 is an enlarged plan view of a display area including a plurality of pixels. For example, FIG. 5 is an enlarged plan view of a display area including one pixel. For example, FIG. 6 is an enlarged plan view of a display area including a plurality of pixels.

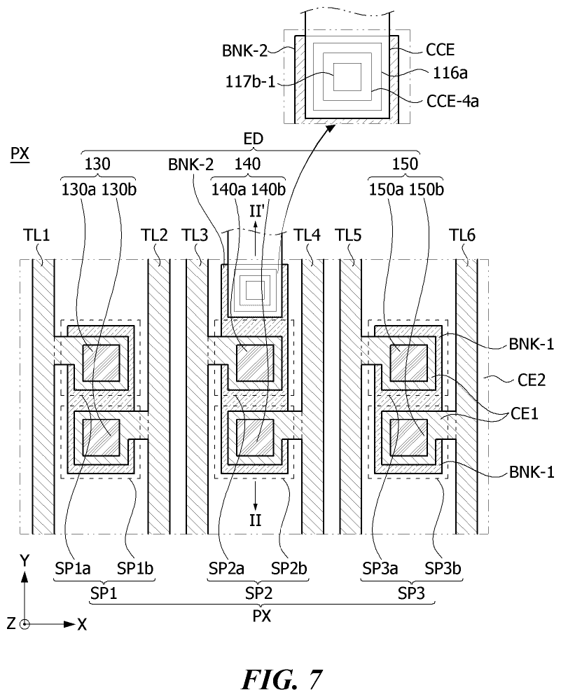

In FIG. 5, only a plurality of signal lines TL, a plurality of communication lines NL, a plurality of first electrodes (or first driving electrodes) CE1, a plurality of banks BNK, and a plurality of light emitting elements ED are illustrated, but embodiments of the present disclosure are not limited thereto. FIGS. 6 and 7 is an enlarged plan view in which a plurality of second electrodes (or second driving electrodes) CE2 are additionally disposed in FIG. 5. Here, a plurality of banks BNK may include a first bank BNK-1 and a second bank BNK-2.

Referring to FIG. 5, a plurality of pixels PX including a plurality of sub-pixels may be disposed in the display area AA. Each of the plurality of sub-pixels includes a light emitting element ED and may independently emit light. The plurality of sub-pixels may form a plurality of rows and a plurality of columns and may be arranged in a matrix form, but configurations of the present disclosure are not limited thereto.

A plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, the other may be a green sub-pixel, and the rest may be a blue sub-pixel. Types of a plurality of sub-pixels are examples, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a first-first sub-pixel SP1a and a first-second sub-pixel SP1b. The pair of second sub-pixels SP2 may include a second-first sub-pixel SP2a and a second-second sub-pixel SP2b.

The pair of third sub-pixels SP3 may include a third-first sub-pixel SP3a and a third-second sub-pixel SP3b. For example, one pixel PX may include a first-first sub-pixel SP1a, a first-second sub-pixel SP1b, a second-first sub-pixel SP2b, a third-first sub-pixel SP3a, and a third-second sub-pixel SP3b, but embodiments of the present disclosure are not limited thereto.

A plurality of sub-pixels constituting one pixel PX may be variously arranged. For example, in one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of a plurality of sub-pixels constituting one pixel PX are exemplary, and configurations of the present disclosure are not limited thereto.

A plurality of signal lines TL may be disposed in a region between the plurality of sub-pixels. The plurality of signal lines TL may extend in a column direction between the plurality of sub-pixels. The plurality of signal lines TL may be lines that transmit an anode voltage from the pixel driving circuit PD to a plurality of sub-pixels. For example, the plurality of signal lines TL may be electrically connected to the plurality of pixel driving circuits PD and the first electrode CE1 of the plurality of sub-pixels.

The anode voltage output from the pixel driving circuit PD may be transferred to the first electrodes CE1 of a plurality of sub-pixels through a plurality of signal lines TL. For example, the first electrode CE1 may be an electrode electrically connected to the anode electrode 134 of the light emitting element ED. Accordingly, the anode voltage from the signal line TL may be transferred to the anode electrode 134 of the light emitting element ED through the first electrode CE1.

Accordingly, instead of forming a plurality of transistors and storage capacitors in each of the plurality of sub-pixels, the structure of the display device 1000 may be simplified by using the pixel driving circuit PD in which the plurality of pixel circuits are integrated. Also, as circuits disposed in each of the plurality of sub-pixels are integrated in one pixel driving circuit PD, high efficiency and low power driving may be possible.

A plurality of signal lines TL may include a first signal line TL1, a second signal line TL2, a third signal line TL3, a fourth signal line TL4, a fifth signal line TL5 and a sixth signal line TL6. Each of the first signal line TL1 and the second signal line TL2 may be electrically connected to each of a pair of first sub-pixels SP1. The third signal line TL3 and the fourth signal line TL4 may be electrically connected to each of a pair of second sub-pixels SP2. The fifth signal line TL5 and the sixth signal line TL6 may be electrically connected to each of a pair of third sub-pixels SP3.

The first signal wire TL1 may be positioned on one side of the pair of first sub-pixels SP1, and the second signal wire TL2 may be positioned on the other side of the pair of first sub-pixels SP1. The first signal wire TL1 may be electrically connected to the first electrode CE1 of one, e.g., the first-first pair of first sub-pixels SP1. The second signal wire TL2 may be electrically connected to the first electrode CE1 of the other, e.g., the first-second sub-pixel SP1b, of the pair of first sub-pixels SP1.

The third signal wire TL3 may be positioned on one side of the pair of second sub-pixels SP2, and the fourth signal wire TL4 may be positioned on the other side of the pair of second sub-pixels SP2. For example, the third signal wire TL3 may be positioned adjacent to the second signal wire TL2. The third signal wire TL3 may be electrically connected to the first electrode CE1 of one, e.g., the second-first sub-pixel SP2a, of the pair of second sub-pixels SP2. The fourth signal wire TL4 may be electrically connected to the first electrode CE1 of the other, e.g., the second-second sub-pixel SP2b, of the pair of second sub-pixels SP2.

The fifth signal wire TL5 may be positioned on one side of the pair of third sub-pixels SP3, and the sixth signal wire TL6 may be positioned on the other side of the pair of third sub-pixels SP3. For example, the fifth signal wire TL5 may be positioned adjacent to the fourth signal wire TL4. The sixth signal wire TL6 may be positioned adjacent to the first signal wire TL1, which is connected to an adjacent pixel PX. The fifth signal wire TL5 may be electrically connected to the first electrode CE1 of one, e.g., the third-first sub-pixel SP3a, of the pair of third sub-pixels SP3. The sixth signal wire TL6 may be electrically connected to the first electrode CE1 of the other, e.g., the third-second sub-pixel SP3b, of the pair of third sub-pixels SP3.

The plurality of signal wires TL may be made of a conductive material. For example, the plurality of signal wires TL may be formed of a conductive material, such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the plurality of signal wires TL may have a multilayer structure of a conductive material. For example, the plurality of signal wires TL may have a multilayer structure of titanium (Ti)/aluminum (Al)/titanium (Ti)/indium tin oxide (ITO), but the embodiments of the present disclosure are not limited thereto.

The plurality of communication wires NL may be arranged in a region between the plurality of pixels PX. The plurality of communication wires NL may extend in a row direction in the region between the plurality of pixels PX. The plurality of communication wires NL may be arranged in a region between the plurality of second electrodes (CE2), and may not overlap the plurality of second electrodes CE2. For example, the plurality of communication wires NL may be wires used for short-range communication, such as near field communication (NFC). The plurality of communication wires NL may function as an antenna. For example, the plurality of communication wires NL may be a plurality of connection wires or the like, but the embodiments of the present disclosure are not limited thereto.

According to the present disclosure, the bank BNK may be positioned in each of the plurality of sub-pixels. A plurality of banks BNK may include a plurality of first banks BNK-1 and a plurality of second banks BNK-2. In addition, the second bank BNK-2 may have an area larger than that of the first bank BNK-1. Particularly, in order to connect the contact electrode CCE and the second electrode CE2, the contact hole 117b-1 may be formed in the second optical layer 117b disposed on the second bank BNK-2, and thus the area of the second bank BNK-2 may be formed larger than that of the first bank BNK-1. In addition, since it is not necessary to form a contact hole for connecting the contact electrode CCE and the second electrode CE2 on a plurality of first banks BNK-1, the area of the first bank BNK-1 need not be formed larger than that of the second bank BNK-2. However, the present disclosure is not limited thereto.

The plurality of banks BNK-1 and BNK-2 may be structures on which the plurality of light emitting element ED are mounted or seated. The banks of each of the plurality of sub-pixels may be configured to be separated from each other. For example, the banks of each of the plurality of sub-pixels may be formed as an island shape. The plurality of banks BNK-1 and BNK-2 may guide the positions of the plurality of light emitting element ED in a transfer process for transferring the plurality of light emitting element ED to the display device 1000. Accordingly, the banks BNK-1 and BNK-2 of the first sub-pixel, the second sub-pixel, and the third sub-pixel to which different types of light-emitting elements ED are transferred can be easily identified. During the transfer process of the plurality of light emitting element ED, the plurality of light emitting element ED may be transferred onto the plurality of banks BNK-1 and BNK-2. The plurality of banks BNK-1 and BNK-2 may be bank patterns or structures, but embodiments of present disclosure are not limited thereto.

Referring to FIG. 7, the first bank BNK-1 of the first sub-pixel SP1, the second bank BNK-2 of the second sub-pixel SP2, and the first bank BNK-1 of the third sub-pixel SP3 may be spaced apart from each other. The first bank BNK-1 of the first sub-pixel SP1, the second bank BNK-2 of the second sub-pixel SP2, and the first bank BNK-1 of the third sub-pixel SP3 may be configured to be separated from each other. Accordingly, the first bank BNK-1 of the first sub-pixel SP1, the second bank BNK-2 of the second sub-pixel SP2, and the first bank BNK-1 of the third sub-pixel SP3, onto which different types of the light emitting element ED are transferred, may be easily distinguished.

The first bank BNK-1 of the first-first sub-pixel SP1a and the first bank BNK-1 of the first-second sub-pixel SP1b may be connected to each other or may be formed to be spaced apart from each other. For example, a first bank BNK-1 of the first-first sub-pixel SP1a in which the same type of light emitting element ED is disposed and a first bank BNK-1 of the first-second sub-pixel SP1b may be connected to each other or may be spaced apart from each other or separated from each other in consideration of a design such as a transfer process requirement and the like. In addition, the second bank BNK-2 of the second-first sub-pixel SP2a and the second bank BNK-2 of the second-second sub-pixel SP2b may be connected to each other or may be formed to be spaced apart from each other. In addition, the first bank BNK-1 of the third-first sub-pixel SP3a and the first bank BNK-1 of the third-second sub-pixel SP3b may be connected to each other or may be formed to be spaced apart from each other.

Accordingly, the first bank BNK-1 of the pair of first sub-pixels SP1, the second bank BNK-2 of the pair of second sub-pixels SP2, and the first bank BNK-1 of the pair of third sub-pixels SP3 may be variously formed, and embodiments of the present disclosure are not limited thereto.

For example, the plurality of banks BNK-1 and BNK-2 may be formed of an organic insulating material. The plurality of banks BNK-1 and BNK-2 may be configured as a single layer or a multi-layer of the organic insulating material. For example, the plurality of banks BNK-1 and BNK-2 may be formed of a photoresist, polyimide (PI), or acryl-based material, but the embodiments of present disclosure are not limited thereto.

The first electrode CE1 may be positioned in each of the plurality of sub-pixels. The first electrode CE1 may be positioned on the banks BNK-1 and BNK-2. For example, the first electrodes CE1 may be positioned on the banks BNK-1 and BNK-2. The first electrode CE1 may be electrically connected to one of the plurality of signal lines TL.

At least a portion of the first electrode CE1 may extend outside of the banks BNK-1 and BNK-2 and be electrically connected to the signal wire TL closest to the first electrode CE1. For example, a portion of the first electrode CE1 of the first-first sub-pixel SP1a may extend to one side region of the first-first sub-pixel SP1a and be electrically connected to the first signal wire TL1, and a portion of the first electrode CE1 of the first-second sub-pixel SP1b may extend to the opposite side region of the first-second sub-pixel SP1b and be electrically connected to the second signal wire TL2.

A portion of the first electrode CE1 of the second-first sub-pixel SP2a may extend to one side area of the second-first sub-pixel SP2a to be electrically connected to the third signal line TL3, and a portion of the first electrode CE1 of the second-second sub-pixel SP2b may extend to the other side area of the second-second sub-pixel SP2b to be electrically connected to the fourth signal line TL4. A portion of the first electrode CE1 of the third-first sub-pixel SP3a may extend to one side area of the third-first sub-pixel SP3a to be electrically connected to the fifth signal line TL5, and a portion of the first electrode CE1 of the third-second sub-pixel SP3b may extend to the other side area of the third-second sub-pixel SP3b to be electrically connected to the sixth signal line TL6.

The first electrode CE1 may be electrically connected to the anode electrode 134 of the light emitting element ED, and may transmit the anode voltage from the pixel driving circuit PD to the light emitting element ED of each of the plurality of sub-pixels through the signal wire TL. Different voltages may be applied to the respective first electrodes CE1 of the plurality of sub-pixels according to an image to be displayed. For example, different voltages may be applied to the respective first electrodes CE1 of the plurality of sub-pixels. Accordingly, the first electrode CE1 may be a pixel electrode, and the embodiments of the present disclosure are not limited thereto.

The first electrode CE1 may be formed of a conductive material. For example, the first electrode CE1 may be formed integrally with a plurality of signal lines TLs. For example, the first electrode CE1 may be formed of the same conductive material as a plurality of signal lines TLs, but embodiments of the present disclosure are not limited thereto. For example, the first electrode CE1 may be formed of a multi-layered structure of titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but embodiments of the present disclosure are not limited thereto. For another example, the first electrode CE1 may be formed of a multi-layered structure of a conductive material. For example, a plurality of first electrodes CE1 may be formed of a multi-layered structure of titanium (Ti)/aluminum (Al)/titanium (Ti)/indium tin oxide (ITO), but embodiments of the present disclosure are not limited thereto.

A light emitting element ED may be disposed in each of a plurality of sub-pixels. A plurality of light emitting elements ED may be any one of a light-emitting diode (LED) and a micro light-emitting diode (Micro LED), but embodiments of the present disclosure are not limited thereto. A plurality of light emitting elements ED may be disposed on the banks BNK-1 and BNK-2 and the first electrode CE1. A plurality of light emitting elements ED may be disposed on the first electrode CE1 and may be electrically connected to the first electrode CE1. Accordingly, the light emitting element ED may emit light by receiving the anode voltage from the pixel driving circuit PD through the signal line TL and the first electrode CE1.

The plurality of light emitting element ED may include a first light emitting element 130, a second light emitting element 140, and a third light emitting element ED 150. The first light emitting element ED 130 may be positioned in the first sub-pixel SP1. The second light emitting element ED 140 may be positioned in the second sub-pixel SP2. The third light emitting element ED 150 may be positioned in the third sub-pixel SP3. For example, one of the first light emitting element ED 130, the second light emitting element ED 140, and the third light emitting element ED 150 may be a red light emitting element ED, another one may be a green light emitting element ED, and the remaining one may be a blue light emitting element ED, but the embodiments of the present disclosure are not limited thereto. Accordingly, by combining red light, green light, and blue light emitted from the plurality of light emitting element EDs ED, various colors of light including white may be implemented. The types of the plurality of light emitting element ED are merely exemplary, and the embodiments of the present disclosure are not limited thereto.

The first light emitting element 130 may include a first-first light emitting element 130a disposed in the first-first sub-pixel SP1a and a first-second light emitting element 130b disposed in the first-second sub-pixel SP1b. The second light emitting element 140 may include a second-first light emitting element 140a disposed in the second-first sub-pixel SP2a and a second-second light emitting element 140b disposed in the second-second sub-pixel SP2b. The third light emitting element 150 may include a third-first light emitting element 150a disposed in the third-first sub-pixel SP3a and a (third-second light emitting element 150b) disposed in the (third-second sub-pixel SP3b).

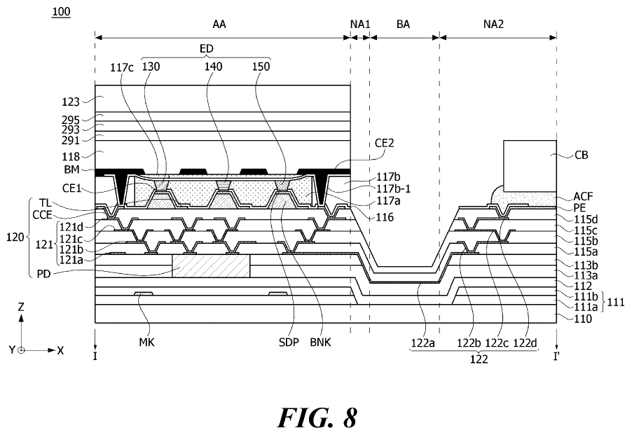

Referring to FIGS. 6 and 7, the second electrode CE2 may be positioned in each of the plurality of sub-pixels. The second electrode CE2 may be positioned on the light emitting element ED. The second electrode CE2 may be electrically connected to the pixel driving circuit (PD of FIG. 8) through the plurality of contact electrodes CCE.

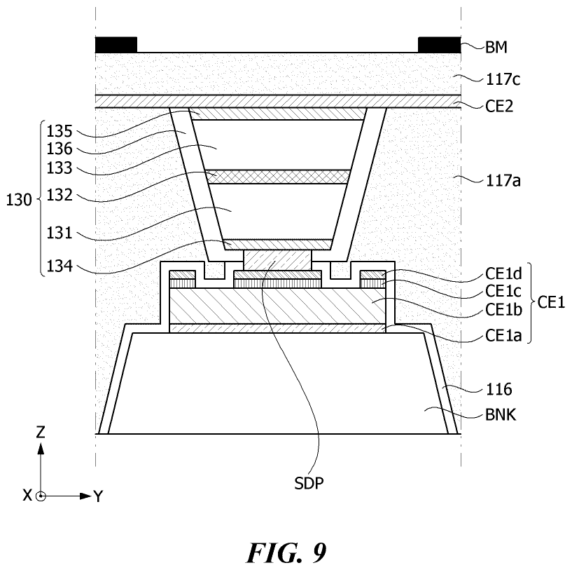

For example, the second electrode CE2 may be electrically connected to a cathode electrode (135 of FIG. 9) of the light emitting element ED and may transmit a cathode voltage from the pixel driving circuit PD to the light emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light emitting element ED. Accordingly, the second electrode CE2 may be a common electrode, but the embodiments of the present disclosure are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, the second electrodes CE2 of at least some sub-pixels may be shared. For example, the second electrodes CE2 of at least some of the plurality of pixels PX arranged in the same row may be connected to each other. For example, a single second electrode CE2 may be provided for the plurality of pixels PX. One second electrode CE2 may be provided for every n sub-pixels.

For example, some of the second electrodes CE2 of the plurality of sub-pixels may be spaced apart or separated from each other. For example, the second electrode CE2 connected to the pixels PX in an n^{th} row and the second electrode CE2 connected to the pixels PX in an (n+1)th row may be spaced apart or separated from each other. For example, the plurality of second electrodes CE2 may be spaced apart from each other with the plurality of communication wires NL, which extend in the row direction, interposed therebetween.

The plurality of second electrodes CE2 may be made of a transparent conductive material, but the embodiments of the present disclosure are not limited thereto. The plurality of second electrodes CE2 may be made of a transparent conductive material, allowing light emitted from the micro-LED ED to be directed upward through the second electrode CE2. For example, the second electrode CE2 may be made of a transparent conductive material such as indium tin oxide (ITO), indium zinc oxide (IZO), or indium gallium zinc oxide (IGZO), but the embodiments of the present disclosure are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. A plurality of contact electrodes CCEs may be electrically connected to a plurality of second electrodes CE2 through contact holes 117b-1 formed in the second optical layer 117b positioned on a plurality of second banks BNK-2.

The plurality of contact electrodes CCE may be positioned between the substrate 110 and the plurality of second electrodes CE2 and may transmit the cathode voltage from the pixel driving circuit PD to the second electrodes CE2.

For example, when using a micro-LED as the light emitting element ED, a plurality of micro-LEDs may be formed on a wafer and transferred to the substrate 110 of the display device 1000 to fabricate the display device 1000. In the process of transferring the plurality of light emitting element ED having a fine size from the wafer to the substrate 110, various defects may occur. For example, in some sub-pixels, a transfer failure may occur where the light emitting element ED is not transferred, and in some other sub-pixels, a defect may occur where the light emitting element ED is transferred to an incorrect position due to an alignment error. Additionally, even if the transfer process is normally performed, the transferred light emitting element ED itself may be defective. Therefore, in the transfer process of the plurality of light emitting element ED, in consideration of defects, the plurality of light emitting element ED that emit light of the same color may be transferred onto one sub-pixel. A lighting test may be performed on the plurality of light emitting element ED and one light emitting element ED that is finally determined to be normal may be used.

For example, a first-first light-emitting element 130a and a first-second light-emitting element 130b may be transferred together onto one pixel PX, and their defect states (for example, whether there is a defect) may be inspected. If both the first-first light-emitting element 130a and the first-second light-emitting element 130b are determined to be normal, the first-first light-emitting element 130a may be used and the first-second light-emitting element 130b may remain unused. In another example, if, among the first-first light emitting element 130a and the first-second light-emitting element 130b, the first-second light-emitting element 130b is determined to be normal, the first-first light-emitting element 130a may remain unused and the first-second light-emitting element may be used. Accordingly, even if a plurality of light-emitting element ED that emit light of the same color are transferred onto one pixel PX, ultimately, one of the light-emitting element ED may be used.

Thus, in a pair of light-emitting element ED, one may be a main (or primary) light-emitting element ED, while the other may be a redundancy light-emitting element ED. The redundancy light-emitting element ED may be an extra light-emitting element ED that is transferred in preparation for a defect in the main light-emitting element ED. The redundant light-emitting element may be used as a replacement in the event of a failure of the main light-emitting element ED. Thus, by transferring both the main light-emitting element ED and the redundancy light-emitting element ED to one pixel PX, degradation in display quality due to defects in the main light-emitting element ED or the redundancy light-emitting element ED may be minimized or reduced.

For example, the first-first light emitting element 130a, the second-first light emitting element 140a, and the third-first light emitting element 150a transferred to one pixel PX may be used as the main light emitting element ED, and the first-second light emitting element 130b, the second-second light emitting element 140b, and the third-second light emitting element 150b may be used as the redundancy light emitting element ED.

FIG. 8 is a cross-sectional view of a display device according to an embodiment of the present disclosure. FIG. 9 is an enlarged cross-sectional view of a display device according to an embodiment of the present disclosure. For example, FIG. 8 is a cross-sectional view taken along the line I-I′ of FIG. 3, the first and second non-display areas NA1 and NA2, and the bending area BA.

Referring to FIG. 8, a buffer layer 111 may be disposed in the remaining area of the substrate 110 except for the bending area BA. The buffer layer 111 may include a first buffer layer 111a and a second buffer layer 111b.

The first buffer layer 111a and the second buffer layer 111b may be positioned in the display area AA, the first non-display area NA1, and the second non-display area NA2. The first buffer layer 111a and the second buffer layer 111b may reduce the permeation of moisture or impurities through the substrate 110. The first buffer layer 111a and the second buffer layer 111b may be made of an inorganic insulating material. For example, the first buffer layer 111a and the second buffer layer 111b may be configured as a single layer or multi-layer of silicon oxide (SiOx) or silicon nitride (SiNx), but the embodiments of the present disclosure are not limited thereto.

The non-display area NA may include a first non-display area NA1, a bending area BA, and a second non-display area NA2. The first and second buffer layers 111a and 111b may be disposed in the first and second non-display areas NA1 and NA2, and may be removed from the bending area BA. For example, the buffer layer 111 may be formed of a single layer or multiple layers of silicon oxide (SiOx) or silicon nitride (SiNx), which is an inorganic film material, but embodiments of the present disclosure are not limited thereto. For example, portions of the first buffer layer 111a and the second buffer layer 111b on the bending area BA may be removed. The upper surface of the substrate 110 located in the bending area BA may be exposed from the first buffer layer 111a and the second buffer layer 111b. By removing the first buffer layer 111a and the second buffer layer 111b made of the inorganic insulating material from the bending area BA, cracks in the first buffer layer 111a and the second buffer layer 111b that may occur during bending may be minimized or reduced.

A plurality of alignment keys MK may be arranged between the first buffer layer 111a and the second buffer layer 111b. The plurality of alignment keys MK may be configured to identify the position of the pixel driving circuit PD during the fabricating process of the display device 1000. For example, the plurality of alignment keys MK may be configured to align the position of the pixel driving circuit PD transferred onto an adhesive layer 112. In another example, the plurality of alignment keys MK may be omitted.

The adhesive layer 112 may be positioned on the second buffer layer 111b. The adhesive layer 112 may be positioned in the display area AA, the first non-display area NA1, the bending area BA, and the second non-display area NA2. In another example, at least a portion of the adhesive layer 112 may be removed from the non-display area NA that includes the bending area BA. For example, the adhesive layer 112 may be made of any one of an adhesive polymer, epoxy resin, UV-curable resin, a polyimide-based material, an acrylate-based material, a urethane-based material, or polydimethylsiloxane (PDMS), but the embodiments of the present disclosure are not limited thereto.

In the display area AA, the pixel driving circuit PD may be positioned on the adhesive layer 112. When the pixel driving circuit PD is implemented as a driver or a pixel driver, the driver may be mounted on the adhesive layer 112 through a transfer process, but the embodiments of the present disclosure are not limited thereto.

A first protective layer 113a and a second protective layer 113b may be positioned on the top or side surfaces of the adhesive layer 112 and the pixel driving circuit PD. The first protective layer 113a and the second protective layer 113b may be positioned to surround the side surface of the pixel driving circuit PD, but the embodiments of the present disclosure are not limited thereto. For example, the second protective layer 113b may be positioned to cover at least a portion of the top surface (also referred to as upper surface) of the pixel driving circuit PD. For example, at least one of the first protective layer 113a and the second protective layer 113b positioned in the bending area BA may be omitted.

For example, the first protective layer 113a may be entirely positioned over the display area AA and the non-display area NA, and the second protective layer 113b may be partially positioned over the display area AA, the first non-display area NA1, and the second non-display area NA2. For example, a portion of the second protective layer 113b in the bending area BA may be removed. However, the embodiments of the present disclosure are not limited thereto.

The first protective layer 113a and the second protective layer 113b may be formed of an organic insulating material, but the embodiments of the present disclosure are not limited thereto. For example, the first protective layer 113a and the second protective layer 113b may be formed of photoresist, polyimide (PI), or a photo acryl-based material, but the embodiments of the present disclosure are not limited thereto. For example, the first protective layer 113a and the second protective layer 113b may be an overcoating layer or an insulating layer, but the embodiments of the present disclosure are not limited thereto.

A plurality of first connection wires (or connection electrodes) 121 may be arranged on the second protective layer 113b in the display area AA. The plurality of first connection wires 121 may be wires for electrically connecting the pixel driving circuit PD to other components. For example, the pixel driving circuit PD may be electrically connected to the plurality of signal wires TL, the plurality of contact electrodes CCE, and the like through the plurality of first connection wires 121. For example, the plurality of first connection wires 121 may include a first-first connection wire 121a, a first-second connection wire 121b, a 1-3 connection wire 121c, and a first-fourth connection wire 121d, and the first-first connection wire 121a, the first-second connection wire 121b, the 1-3 connection wire 121c, and the first-fourth connection wire 121d may be electrically connected to each other through contact holes formed in insulating layers between the connection wires, but the embodiments of the present disclosure are not limited thereto.

For example, a plurality of first-first connection wirings 121a may be disposed on the second protective layer 113b. A plurality of first-first connection wirings 121a may be electrically connected to the pixel driving circuit PD. A plurality of first-first connection wirings 121a may transfer voltages output from the pixel driving circuit PD to the first electrode CE1 or the second electrode CE2.

For example, the first and second protective layers 113a and 113b may be formed of an organic insulating material. For example, the first and second protective layers 113a and 113b may be formed of a photo resist, polyimide (PI), a photo acryl-based material, or the like, but embodiments of the present disclosure are not limited thereto. For example, the first protective layer 113a and the second protective layer 113b may be formed of the same material. Embodiments of the present disclosure are not limited thereto.

For example, the inorganic insulating layer (not shown) may be disposed on the second protective layer 113b. the inorganic insulating layer (not shown) may be formed of a single layer or multiple layers of silicon oxide (SiOx) or silicon nitride (SiNx), which is an inorganic film material, but embodiments of the present disclosure are not limited thereto.

A first organic insulating layer 115a may be disposed on the inorganic insulating layer (not shown). The first organic insulating layer 115a may be formed of an organic insulating material, but embodiments of the present disclosure are not limited thereto. For example, the first organic insulating layer 115a may be formed of a photo resist, polyimide (PI), a photo acryl-based material, or the like, but embodiments of the present disclosure are not limited thereto.

In addition, a plurality of first-second connection wirings 121b may be disposed on the first organic insulating layer 115a. A plurality of first-second connection wirings 121b may be connected to or directly connected to the pixel driving circuit PD. For example, a portion of the first-second connection wiring 121b may be directly connected to the pixel driving circuit PD through a contact hole of the first organic insulating layer 115a. Another portion of the first-second connection wiring 121b may be electrically connected to the first-first connection wiring 121a through a contact hole of the first organic insulating layer 115a. However, embodiments of the present disclosure are not limited thereto. The voltage output from the pixel driving circuit PD may be transferred to the first electrode CE1 or the second electrode CE2 through connection wirings different from a plurality of first-second connection wirings 121b.

The second organic insulating layer 115b may be positioned on the plurality of first-second connection wires 121b. The second organic insulating layer 115b may be entirely positioned over the display area AA and the non-display area NA, but the embodiments of the present disclosure are not limited thereto. The second organic insulating layer 115b may be made of an organic insulating material, but the embodiments of the present disclosure are not limited thereto. For example, the first organic insulating layer 115a may be made of photoresist, polyimide (PI), or a photo acryl-based material, but the embodiments of the present disclosure are not limited thereto.

The plurality of first-third connection wires 121c may be positioned on the second organic insulating layer 115b. The plurality of first-third connection wires 121c may be electrically connected to the plurality of first-second connection wires 121b. For example, the 1-3 connection wire 121c may be electrically connected to the first-second connection wire 121b through a contact hole of the second organic insulating layer 115b.

A third organic insulating layer 115c may be positioned on the plurality of first-third connection wires 121c. The third organic insulating layer 115c may be positioned in a region excluding the bending area BA, but the embodiments of the present disclosure are not limited thereto. The third organic insulating layer 115c may be positioned in the display area AA, the first non-display area NA1, and the second non-display area NA2, but the embodiments of the present disclosure are not limited thereto. For example, a portion of the third organic insulating layer 115c positioned in the bending area BA may be removed. The third organic insulating layer 115c may be made of an organic insulating material, but the embodiments of the present disclosure are not limited thereto. For example, the third organic insulating layer 115b may be made of photoresist, polyimide (PI), or a photo acryl-based material, but the embodiments of the present disclosure are not limited thereto.

The plurality of first-fourth connection wires 121d may be positioned on the third organic insulating layer 115c. The plurality of first-fourth connection wires 121d may be electrically connected to the plurality of first-third connection wires 121c. For example, the first-fourth connection wire 121d may be electrically connected to the first-third connection wire 121c through a contact hole of the third insulating layer 115c.

A fourth organic insulating layer 115d may be disposed on a plurality of first-fourth connection wirings 121d. The fourth organic insulating layer 115d may be disposed in the remaining area except for the bending area BA, but embodiments of the present disclosure are not limited thereto. The fourth organic insulating layer 115d may be disposed in the display area AA, the first non-display area NA1, and the second non-display area NA2, but embodiments of the present disclosure are not limited thereto.

In addition, the circuit layer 120 may include a pixel driving circuit PD, a plurality of connection wirings 121 and 122, and signal wirings TL. The present specification is not limited thereto.

According to the present disclosure, a plurality of second connection wires 122 may be positioned on the second protective layer 113b in the non-display area NA. The plurality of second connection wires 122 may be wires for transmitting a signal, which has been transmitted to the pad portion PAD from the flexible circuit board (or flexible film) CB and the printed circuit board 160 (see FIG. 1), to the pixel driving circuit PD of the display area AA. For example, the plurality of second connection wires 122 may be electrically connected to the plurality of pad electrodes PE to receive a signal from the flexible circuit board (or flexible film) CB and the printed circuit board 160.

For example, the plurality of second connection wires 122 may extend from the pad portion PAD toward the display area AA to transmit a signal to the wire of the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d.

A plurality of second-first connection wirings 122a may be disposed on the second protective layer 113b. A plurality of second-first connection wirings 122a may extend from the second non-display area NA2 to the bending area BA and the first non-display area NA1. A plurality of second-first connection wirings 122a may transmit signals transmitted from the flexible circuit board (or flexible film) CB and the printed circuit board to the pad unit PAD to the pixel driving circuit PD of the display area AA.

A plurality of second-second connection wirings 122b may be disposed on the inorganic insulating layer (not shown) and the first organic insulating layer 115a. A plurality of second-second connection wirings 122b may be disposed in the second non-display area NA2. The second-second connection wiring 122b may be electrically connected to the second-first connection wiring 122a through a contact hole of the first organic insulating layer 115a. Accordingly, the signal from the flexible circuit board (or flexible film) CB and the printed circuit board may be transmitted to the second-first connection wiring 122a through the second-second connection wiring 122b.

A second-third connection wiring 122c may be disposed on the second organic insulating layer 115b. The second-third connection wiring 122c may be disposed in the second non-display area NA2. The second-third connection wiring 122c may be electrically connected to the second-second connection wiring 122b through a contact hole of the second organic insulating layer 115b. Accordingly, the signal from the flexible circuit board (or flexible film) CB and the printed circuit board may be transmitted to the second-first connection wiring 122a through the second-third connection wiring 122c and the second-second connection wiring 122b.

A third organic insulating layer 115c may be disposed on the second organic insulating layer 115b and the second-third connection wiring 122c. In addition, a second-fourth connection wiring 122d may be disposed on the third organic insulating layer 115c. The second-fourth connection wiring 122d may be disposed in the second non-display area NA2. The second-fourth connection wiring 122d may be electrically connected to the second-third connection wiring 122c through a contact hole of the third organic insulating layer 115c. Therefore, the signal from the flexible film FF and the printed circuit board may be transmitted to the second-first connection wiring 122a through the second-fourth connection wiring 122d, the second-third connection wiring 122c, and the second-second connection wiring 122b.

The plurality of first connection wires 121 and the plurality of second connection wires 122 may be formed of a highly flexible conductive material or any one of various conductive materials used in the display area AA.

For example, the second connection wires 122 in which a part is disposed in the bending area BA may be made of a conductive material having excellent ductility, such as gold (Au), silver (Ag), or aluminum (Al), but embodiments of the present disclosure are not limited thereto.

For another example, the plurality of first connection wires 121 and the plurality of second connection wires 122 may be made of molybdenum (Mo), chromium (Cr), titanium (Ti), nickel (Ni), neodymium (Nd), copper (Cu), an alloy of silver (Ag) and magnesium (Mg), or other alloys thereof, but the embodiments of the present disclosure are not limited thereto.

The fourth organic insulating layer 115d may be positioned on the plurality of first connection wires 121 and the plurality of second connection wires 122. The fourth organic insulating layer 115d may be positioned in a region excluding the bending area BA, but the embodiments of the present disclosure are not limited thereto. The fourth organic insulating layer 115d may be positioned in the display area AA, the first non-display area NA1, and the second non-display area NA2. A portion of the fourth organic insulating layer 115d in the bending area BA may be removed. The fourth organic insulating layer 115d may be made of an organic insulating material, but the embodiments of the present disclosure are not limited thereto. For example, the fourth organic insulating layer 115d may be made of photoresist, polyimide (PI), or a photo acryl-based material, but the embodiments of the present disclosure are not limited thereto.

In the description of FIGS. 8 and 9, for convenience of description, a plurality of banks BNK-1 and BNK-2 will be unified and referred to as a plurality of banks BNK.

In the display area AA, the plurality of banks BNK may be positioned on the fourth organic insulating layer 115d. The plurality of banks BNK may respectively overlap the plurality of sub-pixels. One or more micro-LEDs ED that emit light of the same color may be positioned above each of the plurality of banks BNK.

In addition, a plurality of banks BNK may include first and second banks BNK-1 and BNK-2 having different sizes. For example, the second bank BNK-2 may have a larger area than the first bank BNK-2. Since the contact hole 117b-1 for electrically connecting the contact electrode CCE and the second electrode CE2 may be formed on the second bank BNK-2, the second bank BNK-2 needs to have a larger area than the first bank BNK-2.

A plurality of signal lines TL may be disposed on the fourth organic insulating layer 115d in the display area AA. A plurality of signal lines TL may be disposed in an area between a plurality of banks BNK. For example, a plurality of signal lines TL may be disposed adjacent to any one of a plurality of banks BNK.

The plurality of contact electrodes CCE may be positioned on the third insulating layer 115c in the display area AA. The plurality of contact electrodes CCE may supply the cathode voltage from the pixel driving circuit PD to the second electrode CE2.

The first electrode CE1 may be positioned on the bank BNK. For example, the first electrode CE1 may extend from an adjacent signal wire TL toward the top of the bank BNK. The first electrode CE1 may be positioned on the top and side surfaces of the bank BNK. For example, the first electrode CEL may extend from the signal wire TL on the top surface of the third insulating layer 115c to the side surface of the bank BNK and to the top surface of the bank BNK.

Referring to FIGS. 8 and 9, the first electrode CEL may include a plurality of conductive layers. The first electrode CEL and the contact electrode CCE may be formed by the same process, and each of the first electrode CEL and the contact electrode CCE may include the same plurality of conductive layers. For example, the first electrode CEL may include a first conductive layer CE1a, a second conductive layer CE1b, a third conductive layer CE1c, and a fourth conductive layer CE1d, but the embodiments of the present disclosure are not limited thereto.

The first conductive layer CE1a may be positioned on the bank BNK. The second conductive layer CE1b may be positioned on the first conductive layer CE1a. The third conductive layer CE1c may be positioned on the second conductive layer CE1b. The fourth conductive layer CE1d may be positioned on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxide (ITO), but the embodiments of the present disclosure are not limited thereto.

According to the present disclosure, among the plurality of conductive layers constituting the first electrode CEL, some conductive layers with high reflection efficiency may be configured as an alignment key and/or a reflective plate for aligning the light emitting element ED.

For example, in order to configure the second conductive layer CE1b as a reflective plate, the third conductive layer CE1c and the fourth conductive layer CE1d covering the second conductive layer CE1b may be partially removed or etched. For example, portions of the third conductive layer CE1c and the fourth conductive layer CE1d positioned on the bank BNK may be removed or etched to expose the top surface of the second conductive layer CE1b. For example, in the third conductive layer CE1c and the fourth conductive layer CE1d, a central portion where the solder pattern SDP is positioned and a border portion (or edge portion) may be left, while the remaining portions may be removed. For example, the border portion (or edge portion) of each of the third conductive layer CE1c formed of titanium (Ti) and the fourth conductive layer CE1d formed of indium tin oxide (ITO) may not be etched. Accordingly, it is possible to prevent or obviate another conductive layer of the first electrode CEL from being corroded by a tetramethylammonium hydroxide (TMAH) solution used in the masking process of the first electrode CEL.

According to the present disclosure, the first conductive layer CE1a and the third conductive layer CE1c may be made of titanium (Ti) or molybdenum (Mo). The second conductive layer CE1b may be made of aluminum (Al). The fourth conductive layer CE1d may include a transparent conductive oxide layer, such as indium tin oxide (ITO) or indium zinc oxide (IZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but embodiments of the present disclosure are not limited thereto.

According to the present disclosure, the signal wire TL, the contact electrode CCE, and the pad electrode PE positioned in the same layer as the first electrode CEL may include multiple layers of a conductive material, but the embodiments of the present disclosure are not limited thereto. For example, the signal line TL, the contact electrode CCE, and the pad electrode PE may be formed of a multilayer of indium tin oxide (ITO)/titanium (Ti)/aluminum (Al)/titanium (Ti), but embodiments of the present disclosure are not limited thereto.

According to the present disclosure, the solder pattern SDP may be positioned on the first electrode CEL in each of the plurality of sub-pixels. The solder pattern SDP may bond the micro-LED ED to the first electrode CE1 to electrically connect the first electrode CE1 to the micro-LED ED. For example, the first electrode CE1 and the anode electrode 134 of the micro-LED ED may be electrically connected to each other through eutectic bonding using the solder pattern SDP, but the embodiments of the present disclosure are not limited thereto. For example, when the solder pattern SDP be made of indium (In), and the anode electrode 134 of the micro-LED ED be made of gold (Au), the solder pattern SDP and the anode electrode 134 may be bonded by applying heat and pressure during the transfer process of the micro-LED ED. Through eutectic bonding, the micro-LED ED may be bonded to the solder pattern SDP and the first electrode CE1 without a separate adhesive material. For example, the solder pattern SDP may be made of indium (In), tin (Sn), or an alloy thereof, but the embodiments of the present disclosure are not limited thereto. For example, the solder pattern SDP may be a bonding pad or a joining pad, but the embodiments of the present disclosure are not limited thereto.

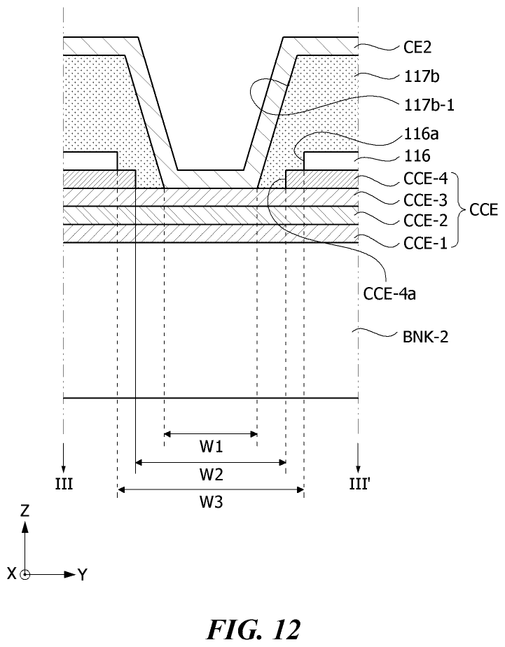

In addition, referring to FIG. 9, an insulating layer 116 may be disposed on the fourth organic insulating layer 115d, the first electrode CE1 and a bank BNK. For example, the insulating layer 116 may be disposed in the entire display area AA and the non-display area NA. As will be described with reference to FIG. 12, an opening 116a (see FIG. 12) may be formed in the insulating layer 116 disposed in the first non-display area NAL. For example, the insulating layer 116 may be formed of a single layer or multiple layers of silicon oxide (SiOx) or silicon nitride (SiNx), which is an inorganic film material, but embodiments of the present disclosure are not limited thereto.

According to the present disclosure, the insulating layer 116 serving as the passivation layer may be disposed on a plurality of signal lines TL, a plurality of first electrodes CE1, a plurality of contact electrodes CCE, and a fourth organic insulating layer 115d. For example, the insulating layer 116 may be positioned in the display area AA, the first non-display area NA1, and the second non-display area NA2. A portion of the insulating layer 116 positioned in the bending area BA may be removed. In the second non-display area NA2, a portion of the insulating layer 116 covering the plurality of pad electrodes PE may be removed. Since the insulating layer 116 is positioned to cover the remaining regions other than the bending area BA and the regions where the plurality of pad electrodes PE and the solder pattern SDP are positioned, penetration of moisture or impurities into the light emitting element ED may be reduced. For example, the insulating layer 116 may include a single layer or multiple layers of silicon oxide (SiOx) or silicon nitride (SiNx), but the embodiments of the present disclosure are not limited thereto.

In addition, the insulating layer 116 may include a hole exposing the solder pattern SDP.

In each of the plurality of sub-pixels, the light-emitting element ED may be positioned on the solder pattern SDP. The first light-emitting element 130 may be positioned in the first sub-pixel SP1. The second light-emitting element 140 may be positioned in the second sub-pixel SP2. The third light-emitting element 150 may be positioned in the third sub-pixel SP3.

The light-emitting element ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present disclosure are not limited thereto.

Referring to FIGS. 8 and 9, the first light-emitting element 130 may include the anode electrode 134, a first semiconductor layer 131, an active layer 132, a second semiconductor layer 133, the cathode electrode 135, and an encapsulation film 136, but the embodiments of the present disclosure are not limited thereto. For example, the first light-emitting element 130 may not include the encapsulation film 136. A first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor of a group III-V or a group II-VI and may be doped with an impurity (or dopant). For example, one of the first semiconductor layer 131 and the second semiconductor layer 133 may be a semiconductor layer doped with an n-type impurity, while the other may be a semiconductor layer doped with a p-type impurity, but the embodiments of the present disclosure are not limited thereto. For example, at least one of the first semiconductor layer 131 and the second semiconductor layer 133 may be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto.

For example, the n-type impurity may be silicon (Si), germanium (Ge), selenium (Se), carbon (C), tellurium (Te), tin (Sn), or the like, but embodiments of the present specification are not limited thereto. For example, the p-type impurity may be magnesium (Mg), zinc (Zn), calcium (Ca), strontium (ST), barium (Ba), beryllium (Be), or the like, but embodiments of the present specification are not limited thereto.

For example, each of the first semiconductor layer 131 and the second semiconductor layer 133 may be a nitride semiconductor including an n-type impurity and a nitride semiconductor including a p-type impurity, but embodiments of the present specification are not limited thereto. For example, the first semiconductor layer 131 may be a nitride semiconductor including a p-type impurity, and the second semiconductor layer 133 may be a nitride semiconductor including an n-type impurity, but embodiments of the present specification are not limited thereto.

The active layer 132 may be positioned between the first semiconductor layer 131 and the second semiconductor layer 133. The active layer 132 may emit light by receiving holes and electrons from the first semiconductor layer 131 and the second semiconductor layer 133. For example, the active layer 132 may be configured in one of a single well structure, a multi-well structure, a single quantum well structure, a multi-quantum well (MQW) structure, a quantum dot structure, and a quantum line structure, but the embodiments of the present disclosure are not limited thereto. For example, the active layer 132 may be made of indium gallium nitride (InGaN) or gallium nitride (GaN), but the embodiments of the present disclosure are not limited thereto.

For another example, the active layer 132 may include a well layer and a multi-quantum well (MQW) structure having a barrier layer having a band gap higher than that of the well layer. For example, the active layer 132 may include InGaN as a well layer and AlGaN layer as a barrier layer, but embodiments of the present disclosure are not limited thereto.

The anode electrode 134 may be disposed between the first semiconductor layer 131 and the solder pattern SDP. For example, the anode electrode 134 may electrically connect the first semiconductor layer 131 to the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material capable of eutectic bonding with the solder pattern SDP. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The cathode electrode 135 may be positioned on the second semiconductor layer 133. For example, the cathode electrode 135 may electrically connect the second semiconductor layer 133 to the second electrode CE2. The cathode voltage outputted from the pixel driving circuit PD may be applied to the second semiconductor layer 133 through the contact electrode CCE, the second electrode CE2, and the cathode electrode 135. The cathode electrode 135 may be formed of a transparent conductive material such that light emitted from the micro-LED ED may be directed toward an upper side of the micro-LED ED, but the embodiments of the present disclosure are not limited thereto. For example, the cathode electrode 135 may be formed of a material such as indium tin oxide (ITO), indium zinc oxide (IZO), or indium gallium zinc oxide (IGZO), but the embodiments of the present disclosure are not limited thereto.

The encapsulation film 136 may be positioned on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135.

For example, the encapsulation layer 136 may be disposed on at least a portion of the anode electrode 134 and the cathode electrode 135, for example, on the edge portion (or edge portion or one side) of the anode electrode 134 and the edge portion (or edge portion or one side) of the cathode electrode 135. At least a portion of the anode electrode 134 may be exposed from the encapsulation layer 136 to connect the anode electrode 134 and the solder pattern SDP. For example, at least a portion of the cathode electrode 135 may be exposed from the encapsulation layer 136 to connect the cathode electrode 135 and the second electrode CE2. For example, the encapsulation layer 136 may be formed of an insulating material such as silicon nitride (SiNx) or silicon oxide (SiOx), but embodiments of the present disclosure are not limited thereto.

As another example, the encapsulation layer 136 may have a structure in which a reflective material is dispersed in a resin layer, but embodiments of the present disclosure are not limited thereto. For example, the encapsulation layer 136 may be manufactured as a reflector having various structures, but embodiments of the present disclosure are not limited thereto. Light emitted from the active layer 132 by the encapsulation layer 136 may be reflected upward to improve light extraction efficiency. For example, the encapsulation layer 136 may be a reflective layer, but embodiments of the present disclosure are not limited thereto.

Although the light emitting element ED has been described as a vertical type structure according to the present disclosure, embodiments of the present disclosure are not limited thereto. For example, the light emitting element ED may have a lateral structure or a flip chip structure.

Although the first light emitting element 130 has been described with reference to FIG. 9, the second light emitting element 140 and the third light emitting element 150 may have substantially the same structure as the first light emitting element 130. For example, the second light emitting element 140 and the third light emitting element 150 may be substantially the same as the first semiconductor layer 131, the active layer 132, the second semiconductor layer 133, the anode electrode 134, the cathode electrode 135, and the encapsulation film 136.

According to the present disclosure, a first optical layer 117a may be positioned on the insulating layer 116 to surround the plurality of light emitting element ED in the display area AA. For example, the first optical layer 117a may be positioned to cover the plurality of light emitting element ED and the bank BNK in regions of the plurality of sub-pixels. For example, the first optical layer 117a may cover the bank BNK, a portion of the passivation layer 116 and the spaces between the plurality of light emitting element ED. The first optical layer 117a may be positioned between the plurality of banks BNK and between the plurality of light emitting element ED included in one pixel PX, or may cover those spaces. For example, the first optical layer 117a may extend in a first direction X and may be separated in a second direction Y. For example, the first optical layer 117a may be positioned between the passivation layer 116 and the second electrode CE2 to surround the side portions of the light emitting element ED and the bank BNK, but the embodiments of the present disclosure are not limited thereto. For example, the first optical layer 117a may be a diffusion layer, a sidewall diffusion layer, or the like, but the embodiments of the present disclosure are not limited thereto.

The first optical layer 117a may be formed of an organic insulating material in which fine particles are dispersed, but the embodiments of the present disclosure are not limited thereto. For example, the first optical layer 117a may be made of siloxane in which fine metal particles such as titanium dioxide (TiO2) particles are dispersed, but the embodiments of the present disclosure are not limited thereto. Light from the plurality of light emitting element ED may be scattered by the fine particles dispersed in the first optical layer 117a and emitted to the outside of the display device 1000. Accordingly, the first optical layer 117a may improve the light extraction efficiency of the light emitted from the plurality of light emitting element ED.

For example, the first optical layer 117a may be positioned in each of the plurality of pixels PX, or may be commonly positioned in some of the pixels PX arranged in the same row, but the embodiments of the present disclosure are not limited thereto. For example, the first optical layer 117a may be positioned in each of the plurality of pixels PX, or a single first optical layer 117a may be shared by the plurality of pixels PX. In another example, each of the plurality of sub-pixels may separately include the first optical layer 117a, but the embodiments of the present disclosure are not limited thereto.

According to the present disclosure, the second optical layer 117b may be disposed on the insulating layer 116 in the display area AA. For example, the second optical layer 117b may be disposed to surround the first optical layer 117a. For example, the second optical layer 117b may be in contact with the side surface of the first optical layer 117a. For example, the second optical layer 117b may be disposed in an area between a plurality of pixels PX. However, embodiments of the present disclosure are not limited thereto, for example, the second optical layer 117b may be a diffusion layer, a diffusion layer window, a window diffusion layer, or the like, but embodiments of the present disclosure are not limited thereto.

The second optical layer 117b may be formed of an organic insulating material, but embodiments of the present disclosure are not limited thereto. The second optical layer 117b may be formed of the same material as the first optical layer 117a, but embodiments of the present disclosure are not limited thereto. For example, the first optical layer 117a may include fine particles, and the second optical layer 117b may not include fine particles. For example, the second optical layer 117b may be formed of siloxane, but embodiments of the present disclosure are not limited thereto.

For example, the thickness of the first optical layer 117a may be less than that of the second optical layer 117b, but embodiments of the present disclosure are not limited thereto. Accordingly, when viewed in a plan view, the region in which the first optical layer 117a is disposed may include a concave portion recessed inwardly from the upper surface of the second optical layer 117b.

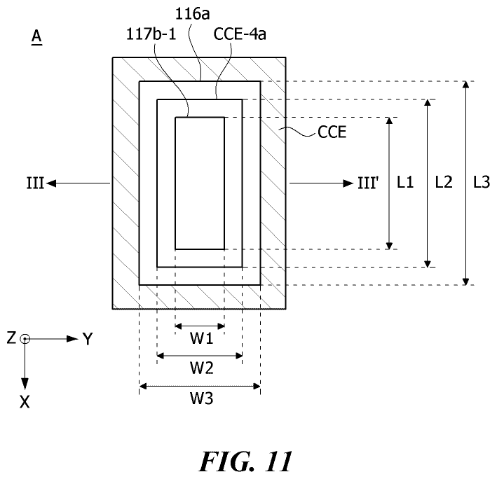

According to the present disclosure, the second electrode CE2 may be disposed on the first optical layer 117a and the second optical layer 117b. For example, the second electrode CE2 may be electrically connected to a plurality of contact electrodes CCE through a contact hole (117b-1 of FIG. 11) of the second optical layer 117b positioned on the bank BNK-2. For example, the second electrode CE2 may be disposed on a plurality of light emitting elements ED. For example, the second electrode CE2 may include a transparent conductive oxide such as indium tin oxide (ITO) or indium zinc oxide (IZO), but embodiments of the present disclosure are not limited thereto. For example, the second electrode CE2 may be disposed to be in contact with the cathode electrode 135. For example, the second electrode CE2 may overlap the first optical layer 117a. For example, the outer plane of the first optical layer 117a may be covered. The second electrode CE2 may continuously extend in the first direction X of the substrate 110.

Accordingly, the substrate 110 may be commonly connected to a plurality of pixels PX arranged in the first direction X. For example, the second electrode CE2 may be commonly connected to a plurality of pixels PX.

According to the present disclosure, the second electrode CE2 may continuously extend on the first optical layer 117a, the second optical layer 117b, and the light emitting element ED. The region in which the first optical layer 117a is disposed may include a concave portion recessed inwardly from the upper surface of the second optical layer 117b. Accordingly, since the first portion of the second electrode CE2 disposed on the first optical layer 117a is disposed along the concave portion, the first portion may be disposed at a lower position than the second portion of the second electrode CE2 disposed on the second optical layer 117b.

In addition, the third optical layer 117c may be disposed on the second electrode CE2. The third optical layer 117c may be disposed to overlap a plurality of light emitting elements ED and the first optical layer 117a. Since the third optical layer 117c is disposed on the second electrode CE2 and a plurality of light emitting elements ED, a stain (Mura) that may occur in some of a plurality of light emitting elements ED may be improved. For example, when a plurality of light emitting elements ED are transferred onto the substrate 110 of the display device 1000, a region in which a gap between a plurality of light emitting elements ED is not uniform due to a process variation or the like may occur. When the spacing between the plurality of light emitting elements ED is non-uniform, the light emitting area of each of the plurality of light emitting elements ED may be non-uniformly disposed, and thus a stain (Mura) may be visually recognized by the user.

Accordingly, since the third optical layer 117c configured to uniformly diffuse light on the plurality of light emitting elements ED is configured, light emitted from some light emitting elements ED may be reduced from being visually recognized like a stain.

Therefore, since the light emitted from the plurality of light emitting elements ED is evenly diffused by the third optical layer 117c and extracted to the outside of the display device 1000, the luminance uniformity of the display device 1000 may be improved.

The third optical layer 117c may be formed of an organic insulating material in which fine particles are dispersed, but embodiments of the present disclosure are not limited thereto. For example, the third optical layer 117c may be formed of siloxane in which fine metal particles such as titanium dioxide (TiO2) particles are dispersed, but embodiments of the present disclosure are not limited thereto. For example, the third optical layer 117c may be formed of the same material as the first optical layer 117a, but embodiments of the present disclosure are not limited thereto. For example, the third optical layer 117c may be a diffusion layer, an upper diffusion layer, or the like, but embodiments of the present disclosure are not limited thereto.

According to the present disclosure, light from a plurality of light emitting elements ED may be scattered by fine particles dispersed in the third optical layer 117c and emitted to the outside of the display device 1000. The third optical layer 117c may evenly mix light emitted from a plurality of light emitting elements ED to further improve luminance uniformity of the display device 1000.

In addition, light extraction efficiency of the display device 1000 may be improved by light scattered from a plurality of fine particles, and thus the display device 1000 may be driven at a low power.

In the display area AA, a black matrix BM may be disposed on the second electrode CE2, the first optical layer 117a, the second optical layer 117b and the third optical layer 117c. For example, the black matrix BM may fill a contact hole of the second optical layer 117b-1. Since the black matrix BM is configured to cover the display area AA, color mixture and reflection of external light of a plurality of sub-pixels may be reduced. For example, since the black matrix BM is disposed within a contact hole 117b-1 in which the second electrode CE2 is connected with the contact electrode CCE, light leakage between a plurality of neighboring sub-pixels may be prevented or reduced.

For example, the black matrix BM may be formed of an opaque material, but embodiments of the present disclosure are not limited thereto. For example, the black matrix BM may be an organic insulating material to which a black pigment or a black dye is added, but embodiments of the present disclosure are not limited thereto.

In the display area AA, a cover layer 118 (see FIG. 12) may be disposed on the black matrix BM. The cover layer 118 may protect an element under the second electrode CE2, for example, the cover layer 118 may be formed of an organic insulating material, but embodiments of the present disclosure are not limited thereto. For example, the cover layer 118 may be formed of a photo resist, polyimide (PI), a photo acryl-based material, or the like, but embodiments of the present disclosure are not limited thereto. For example, the cover layer 118 may be an overcoating layer, an insulating layer, or the like, but embodiments of the present disclosure are not limited thereto.

As shown in FIG. 1, the polarizing layer 293 may be disposed on the cover layer 118 via the first adhesive layer 291. The cover member 120 may be disposed on the polarizing layer 293 via the second adhesive layer 295. For example, the first adhesive layer 291 and the second adhesive layer 295 may include an optically clear adhesive (OCA), an optically clear resin (OCR), a pressure sensitive adhesive (PSA) or the like, but embodiments of the present disclosure are not limited thereto.

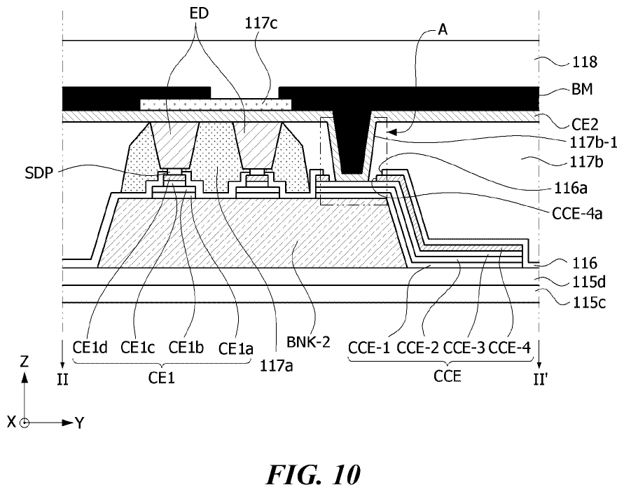

FIG. 10 is a cross-sectional view taken along the line II-II′ of FIG. 7. FIG. 11 is an enlarged plan view of part A in FIG. 10. FIG. 12 is a cross-sectional view taken along line III-III′ in FIG. 11.

Referring to FIGS. 10 and 11, in a display device according to the embodiment of the present specification, a plurality of banks BNK may be disposed on a substrate 110 (see FIG. 8), and a plurality of light-emitting elements ED may be disposed on the plurality of banks BNK.

Here, the plurality of banks BNK may include a plurality of first banks BNK-1 and a plurality of second banks BNK-2. In addition, the plurality of second banks BNK-2 have a greater area than the plurality of first banks BNK-1. Hereinafter, for the sake of convenience, a connection structure of the plurality of light-emitting elements ED, a first electrode CE1, and a contact electrode CCE that are disposed on the second bank BNK-2 will be described. For example, the bank BNK may include the second bank BNK-2.

The first electrode CE1 may be disposed between the second bank BNK-2 and the plurality of light-emitting elements ED.

Here, the first electrode CE1 may be formed of a plurality of conductive layers. For example, the first electrode CE1 may include a first conductive layer CE1a, a second conductive layer CE1b, a third conductive layer CE1c, and a fourth conductive layer CE1d, but the embodiments of the present specification are not limited thereto.

For example, each of the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but the embodiments of the present specification are not limited thereto.

In addition, some of the plurality of conductive layers constituting the first electrode CE1, which have good reflection efficiency, may be formed as an alignment key for aligning the light-emitting element ED and/or a reflector. For example, the second conductive layer CE1b among the plurality of conductive layers of the first electrode CE1 may include a reflective material. For example, the second conductive layer CE1b may include aluminum (Al), but the embodiments of the present specification are not limited thereto. Accordingly, the second conductive layer CE1b may be formed to be a reflector. In addition, due to the high reflection efficiency of the second conductive layer CE1b, the second conductive layer CE1b can be easily identified during the manufacturing process, and thus the location or transfer location of the light-emitting element ED may be aligned based on the second conductive layer CE1b. Therefore, in the display panel 100 according to the present specification, the second conductive layer CE1b, which has a higher light reflectance than the fourth conductive layer CE1d disposed above, may be exposed, and light emitted from the light-emitting element ED may be reflected by the exposed second conductive layer CE1b, thereby improving the light output efficiency of the light-emitting element ED. It is to be noted that although the first electrode CE1 according to various embodiments of the present disclosure is described as including four conductive layers CE1a to CE1d by way of example, but the present disclosure is not limited thereto. For example, two or three conductive layers or five or more conductive layers may be included in the first electrode CE1.

For example, to form the second conductive layer CE1b as a reflector, parts of the third conductive layer CE1c and the fourth conductive layer CE1d that cover the second conductive layer CE1b may be removed or etched to expose an upper surface the second conductive layer CE1b. For example, a central portion and an edge portion of the third conductive layer CE1c and the fourth conductive layer CE1d, in which a solder pattern SDP is disposed, may remain, and the remaining portions not including the central and edge portions may be removed. In addition, the edge portion of each of the third conductive layer CE1c formed of titanium (Ti) and the fourth conductive layer CE1d formed of indium tin oxide (ITO) may not be etched. Accordingly, it is possible to prevent or obviate other conductive layers of the first electrode CEL from being corroded by a tetramethylammonium hydroxide (TMAH) solution used in a masking process of the first electrode CEL.

In addition, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as an indium tin oxide (ITO) or indium zinc oxide (IZO) layer, which has high adhesion to the solder pattern SDP, corrosion resistance, and acid resistance. The embodiments of the present specification are not limited thereto.

In addition, a signal line TL, the contact electrode CCE, and a pad electrode PE (see FIG. 8) that are disposed to be coplanar with the first electrode CE1 may be formed of multiple layers of conductive materials. The embodiments of the present specification are not limited thereto.

The solder pattern SDP may be disposed on the first electrode CE1 disposed below the light-emitting element ED. The solder pattern SDP may bond the light-emitting element ED to the first electrode CEL. The first electrode CEL and the light-emitting element ED may be electrically connected through eutectic bonding using the solder pattern SDP, but the embodiments of the present specification are not limited thereto.

In addition, the contact electrode CCE formed to be coplanar with the first electrode CE1 may be disposed on the second bank BNK-2. The contact electrode CCE may extend to the upper surface and side surfaces of the second bank BNK-2 and may be connected to a pixel driving circuit PD (see FIG. 8) and the pad PE.

The contact electrode CCE formed to be coplanar with the first electrode CE1 may be formed of a plurality of conductive layers. For example, the contact electrode CCE may include a first contact conductive layer CCE-1, a second contact conductive layer CCE-2, a third contact conductive layer CCE-3, and a fourth contact conductive layer CCE-4, but the embodiments of the present specification are not limited thereto.

For example, each of the first contact conductive layer CCE-1, the second contact conductive layer CCE-2, the third contact conductive layer CCE-3, and the fourth contact conductive layer CCE-4 may be formed of titanium (Ti), molybdenum (Mo), aluminum (Al), or titanium (Ti) and indium tin oxide (ITO), but the embodiments of the present specification are not limited thereto.

The fourth contact conductive layer CCE-4 applied as an uppermost layer of the contact electrode CCE may include a transparent conductive oxide layer, such as an indium tin oxide (ITO) or indium zinc oxide (IZO) layer, which is corrosion-resistant and acid-resistant. The embodiments of the present specification are not limited thereto. However, to electrically connect the contact electrode CCE to the second electrode CE2, the contact electrode CCE and the second electrode CE2 may be electrically connected through a contact hole 117b-1 formed in a second optical layer 117b disposed on the contact electrode CCE.

However, since the fourth contact conductive layer CCE-4, which is the uppermost layer of the contact electrode CCE on which the second optical layer 117b is disposed, is formed of ITO, adhesion at an interface between the second optical layer 117b and the fourth contact conductive layer CCE-4 of the contact electrode CCE is not good, thereby causing a delamination phenomenon.

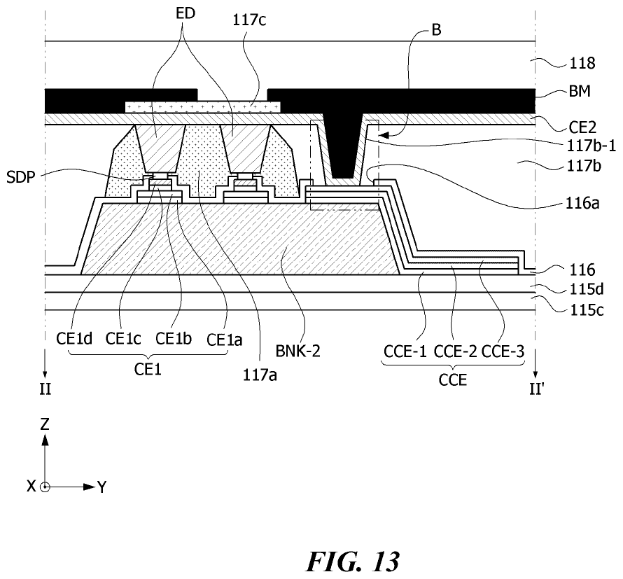

Accordingly, in the present specification, to prevent or reduce the occurrence of the delamination phenomenon, as illustrated in FIGS. 11 and 13, the area below the contact hole 117b-1 formed in the second optical layer 117b disposed between the second electrode CE2 and the contact electrode CCE, for example, the fourth contact conductive layer CCE-4 of the contact electrode CCE, may be removed so that the second electrode CE2 and the contact electrode CCE are in contact with each other. A contact opening CCE-4a may be formed in an area in which a part of the fourth contact conductive layer CCE-4 of the contact electrode CCE is removed.

Accordingly, interfaces may be formed between the first to third contact conductive layers CCE-1, CCE-2, and CCE-3, which have a Ti/Al/Ti stacked structure of the contact electrode CCE, and the second optical layer 117b through the contact opening CCE-4a. Accordingly, since the ITO layer under the contact hole 117b-1 is removed, it is possible to prevent or obviate the delamination phenomenon of the second optical layer 117b.

In addition, referring to FIGS. 9 and 10, an insulating layer 116 may be disposed on the second bank BNK-2, the first electrode CEL, and the contact electrode CCE. Specifically, the insulating layer 116 that serves as a passivation layer may be disposed on a plurality of signal lines TL, a plurality of first electrodes CE1, a plurality of contact electrodes CCE, and a fourth organic insulating layer 115d. For example, the insulating layer 116 may be disposed on a display area AA, a first non-display area NA1, and a second non-display area NA2. A part of the insulating layer 116 disposed in a bending area BA may be removed. A part of the insulating layer 116 covering the plurality of pad electrodes PE in the second non-display area NA2 may be removed. Since the insulating layer 116 is disposed to cover the remaining areas not including the bending area BA and areas in which the plurality of pads 170 and the solder pattern SDP are disposed, it is possible to reduce the penetration of moisture or impurities into the light-emitting element ED. For example, the insulating layer 116 may be formed of a single layer or multiple layers of silicon oxide (SiOx) or silicon nitride (SiNx) that is an inorganic film material, but the embodiments of the present specification are not limited thereto. For example, the insulating layer 116 may be a protective layer, an insulating layer, or the like, but the embodiments of the present specification are not limited thereto.

In addition, referring to FIGS. 11 and 12, an opening 116a may be formed in an area of the insulating layer 116, which is located on the contact opening CCE-4a of the contact electrode CCE on the second bank BNK-2. A width W3 of the opening 116a may be greater than a width W2 of the contact opening CCE-4a of the contact electrode CCE. For example, an area of the opening 116a may be greater than an area of the contact opening CCE-4a. Accordingly, by removing the transparent conductive layer, which is the uppermost layer of the contact electrode located in the contact hole area, for connecting the second electrode CE2 to the contact electrode CCE, for example, a portion of the fourth contact conductive layer CCE-4, to form the contact opening CCE-4a, it is possible to secure a formation margin of the opening 116a of the insulating layer 116 above the contact electrode CCE, thereby improving misalignment.

In addition, the opening 116a of the insulating layer 116 may be formed at a location overlapping the contact opening CCE-4a of the contact electrode CCE.

A first optical layer 117a may be disposed on the insulating layer 116 covering the plurality of light-emitting elements ED on the second bank BNK-2. For example, the first optical layer 117a may be disposed to cover the plurality of light-emitting elements ED and the second bank BNK-2. For example, the first optical layer 117a may cover spaces between the bank BNK, a part of the insulating layer 116, and the plurality of light-emitting elements ED. The first optical layer 117a may be disposed between the plurality of light-emitting elements ED and between the plurality of banks BNK, which are included in one pixel PX, or may cover the plurality of light-emitting elements ED and the plurality of banks BNK. For example, the first optical layer 117a may be disposed to surround side portions of the light-emitting element ED and the bank BNK between the insulating layer 116 and the second electrode CE2, but the embodiments of the present specification are not limited thereto. For example, the first optical layer 117a may be a diffusion layer, a sidewall diffusion layer, or the like, but the embodiments of the present specification are not limited thereto.

The first optical layer 117a may include an organic insulation material having fine particles dispersed therein, but the embodiments of the present specification are not limited thereto. For example, the first optical layer 117a may be formed of siloxane having fine metal particles, such as titanium dioxide (TiO₂) particles, dispersed therein, but the embodiments of the present specification are not limited thereto. Light from the plurality of light-emitting elements ED may be scattered by the fine particles dispersed in the first optical layer 117a and emitted to the outside of a display device 1000. Accordingly, the first optical layer 117a can increase the extraction efficiency of the light emitted from the plurality of light-emitting elements ED.

The second optical layer 117b may be disposed on the insulating layer 116 and the contact opening CCE-4a of the contact electrode CCE. The second optical layer 117b may be in contact with side surfaces of the first optical layer 117a to surround the first optical layer 117a. The second optical layer 117b may be disposed in areas between a plurality of pixels PX. The second optical layer 117b may be disposed to cover a part of the upper surface and side surfaces of the second bank BNK-2.

The second optical layer 117b may be formed of an organic insulation material, but the embodiments of the present specification are not limited thereto. The second optical layer 117b may be formed of the same material as the first optical layer 117a, but the embodiments of the present specification are not limited thereto. For example, the first optical layer 117a may include fine particles, and the second optical layer 117b may not include fine particles.

Here, the contact hole 117b-1 may be formed in an area of the second optical layer 117b, which is located on the second bank BNK-2. The contact hole 117b-1 serves to electrically connect the second electrode CE2 and the contact electrode CCE located below the contact hole 117b-1. In addition, the contact hole 117b-1 may be formed at a location at which the contact opening CCE-4a formed by removing a part of the fourth contact conductive layer CCE-4, which is the uppermost layer of the contact electrode CCE, overlaps the opening 116a of the insulating layer 116 disposed on the contact electrode CCE.

Specifically, it is possible to prevent or obviate the delamination phenomenon of the second optical layer 117b by forming the interface between the second optical layer 117b and the contact electrode CCE through the contact opening CCE-4a formed by removing a part of the transparent conductive layer, which is the uppermost layer of the contact electrode CCE, for example, the ITO layer. Accordingly, it is possible to expect the crack prevention effect when forming the second electrode CE2, which is a subsequent process.

Specifically, referring to FIGS. 11 and 12, a width W1 of a short side of the contact hole 117b-1 may be smaller than a width W2 of a short side of the contact opening CCE-4a formed by removing a part of the fourth contact conductive layer CCE-4, which is the uppermost layer of the contact electrode CCE, and a width W3 of a short side of the opening 116a in the middle of the insulating layer 116 disposed on the contact electrode CCE.

For example, assuming that the width W1 of the short side of the contact hole 117b-1 is 1, the width W2 of the short side of the contact opening CCE-4a formed by removing a part of the fourth contact conductive layer CCE-4, which is the uppermost layer of the contact electrode CCE, may range from about 1.5 to 4.0 and more particularly range from about 1.8 to 3.5. The present embodiment is not limited thereto. In addition, the width W3 of the short side of the opening 116a in the middle of the insulating layer 116 disposed on the contact electrode CCE may range from about 1.8 to 5.0 and more particularly range from about 2.0 to 4.5. The present embodiment is not limited thereto. In other words, the width W2 of the short side of the contact opening CCE-4a may be 1.5 to 4.0 times (more specifically, 1.8 to 3.5 times) larger than the width W1 of the short side of the contact hole 117b-1, and the width W3 of the short side of the opening 116a may be 1.8 to 5.0 times (more specifically, 2.0 to 4.5 times) larger than the width W1 of the short side of the contact hole 117b-1.

A length L1 of a long side of the contact hole 117b-1 may be smaller than a length L2 of a long side of the contact opening CCE-4a formed by removing a part of the fourth contact conductive layer CCE-4, which is the uppermost layer of the contact electrode CCE, and a length L3 of a long side of the opening 116a in the middle of the insulating layer 116 disposed on the contact electrode CCE.

For example, assuming that the length L1 of the long side of the contact hole 117b-1 is 1, the length L2 of the long side of the contact opening CCE-4a formed by removing a part of the fourth contact conductive layer CCE-4, which is the uppermost layer of the contact electrode CCE, may range about 1.1 to 1.7 and more particularly range from about 1.2 to 1.5. The present embodiment is not limited thereto. In addition, the length L3 of the long side of the opening 116a of the insulating layer 116 disposed on the contact electrode CCE may range from about 1.2 to 2.0 and more particularly range from about 1.3 to 1.7. The present embodiment is not limited thereto. In other words, the length L2 of the long side of the contact opening CCE-4a may be 1.1 to 1.7 times (more specifically, 1.2 to 1.5 times) larger than the length L1 of the long side of the contact hole 117b-1, and the length L3 of the long side of the opening 116a may be 1.2 to 2.0 times (more specifically, 1.3 to 1.7 times) larger than the length L1 of the long side of the contact hole 117b-1.

In addition, an area of the contact hole 117b-1 may be smaller than an area of the contact opening CCE-4a formed by removing a part of the fourth contact conductive layer CCE-4, which is the uppermost layer of the contact electrode CCE, and an area of the opening 116a of the insulating layer 116 disposed on the contact electrode CCE. For example, assuming that the area of the contact hole 117b-1 is 1, the area of the contact opening CCE-4a formed by removing a part of the fourth contact conductive layer CCE-4, which is the uppermost layer of the contact electrode CCE, may range from about 1.5 to 4 and more particularly range from 1.7 to 3.0. The present embodiment is not limited thereto. In addition, an area of the opening 116a of the insulating layer 116 disposed on the contact electrode CCE may range from about 1.8 to 4.5 and more particularly, range from 1.7 to 3.5. The present embodiment is not limited thereto. In other words, the area of the contact opening CCE-4a may be 1.5 to 4 times (more specifically, 1.7 to 3.0 times) larger than the area of the contact hole 117b-1, and the area of the opening 116a may be 1.8 to 4.5 times (more specifically, 1.7 to 3.5 times) larger than the area of the contact hole 117b-1.

The second electrode CE2 may be disposed on the first optical layer 117a and the second optical layer 117b. For example, the second electrode CE2 may be electrically connected to a plurality of contact electrodes CCE through the contact hole 117b-1 of the second optical layer 117b, and the opening 116a of the insulating layer 116 and the contact opening CCE-4a of the contact electrode CCE under the contact hole 117b-1.

Accordingly, the second electrode CE2 may be electrically connected to the contact electrode CCE from which the transparent conductive layer of the fourth contact conductive layer CCE-4, which is the uppermost layer, for example, an area of the ITO layer, is removed, thereby preventing or reduce cracks in the second electrode CE2.

In addition, the third optical layer 117c may be disposed on the second electrode CE2 to overlap the plurality of light-emitting elements ED and the first optical layer 117a that are disposed on the second bank BNK-2. Since the third optical layer 117c is disposed on the second electrode CE2 and the plurality of light-emitting elements ED, it is possible to eliminate spots (mura) that may occur in some of the plurality of light-emitting elements ED.

Accordingly, since the light emitted from the plurality of light-emitting elements ED is uniformly diffused by the third optical layer 117c and extracted to the outside of the display device 1000, it is possible to improve the luminance uniformity of the display device 1000.

For example, the third optical layer 117c may be formed of the same material as the first optical layer 117a, but the embodiments of the present specification are not limited thereto. For example, the third optical layer 117c may be a diffusion layer, an upper diffusion layer, etc., but the embodiments of the present specification are not limited thereto.

Light from the plurality of light-emitting elements ED may be scattered by the fine particles dispersed in the third optical layer 117c and emitted to the outside of the display device 1000. The third optical layer 117c may uniformly mix the light emitted from the plurality of light-emitting elements ED, thereby further improving the luminance uniformity of the display device 1000. In addition, it is possible to increase the light extraction efficiency of the display device 1000 by the light scattered by the fine particles, thereby enabling low-power driving of the display device 1000.

In the display area AA, the black matrix BM may be disposed on the second electrode CE2, the first optical layer 117a, the second optical layer 117b, and the third optical layer 117c.

In addition, in the display area AA, a cover layer 118 may be disposed on the black matrix BM.

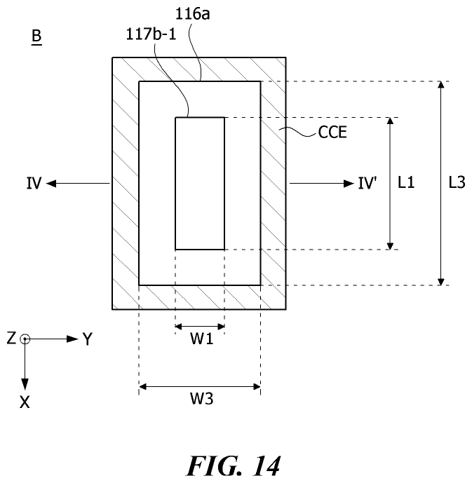

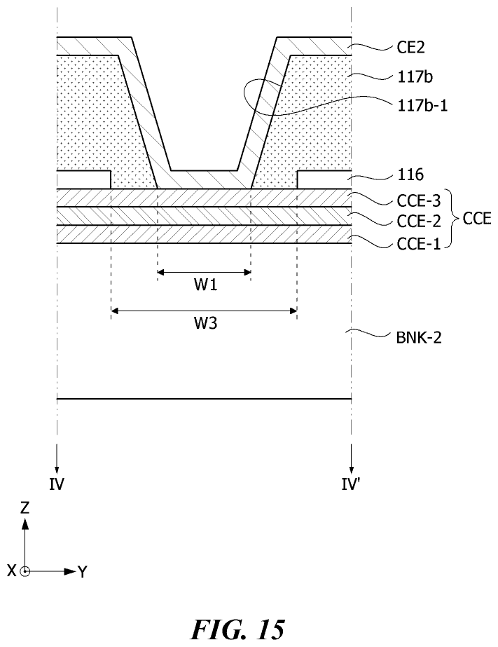

FIG. 13 is a cross-sectional view taken along line II-II′ of FIG. 7, illustrating a cross-sectional view of a display device according to another embodiment of the present disclosure. FIG. 14 is an enlarged plan view of portion B in FIG. 14. FIG. 15 is a cross-sectional view along line IV-IV′ in FIG. 14.

FIGS. 13 to 15 are views illustrating a display device according to another embodiment of the present specification, and another embodiment of the present specification may be formed of the same components as the display device according to one embodiment of the present specification of FIGS. 10 to 12 with the exception that the entirety of the fourth contact conductive layer CCE-4, which is the uppermost layer of the contact electrode CCE, is removed.

Here, a structure in which the contact electrode CCE is electrically connected to the second electrode CE2 in a state in which the fourth contact conductive layer CCE-4, which is the uppermost layer of the contact electrode CCE, has been removed will be mainly described.

Referring to FIGS. 13 to 15, in the display device according to another embodiment of the present specification, a plurality of banks BNK may be disposed on a substrate 110 (see FIG. 8), and a plurality of light-emitting elements ED may be disposed on the plurality of banks BNK.

Here, the plurality of banks BNK may include a plurality of first banks BNK-1 and a plurality of second banks BNK-2. In addition, the plurality of second banks BNK-2 have a greater area than the plurality of first banks BNK-1. Hereinafter, for the sake of convenience, a connection structure of the plurality of light-emitting elements ED, a first electrode CE1, and a contact electrode CCE that are disposed on the second bank BNK-2 will be described.

The first electrode CE1 may be disposed between the second bank BNK-2 and the plurality of light-emitting elements ED. The first electrode CE1 may be formed of a plurality of conductive layers. For example, the first electrode CE1 may include the first conductive layer CE1a, the second conductive layer CE1b, the third conductive layer CE1c, and the fourth conductive layer CE1d, but the embodiments of the present specification are not limited thereto.

For example, each of the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but the embodiments of the present specification are not limited thereto.

To form the second conductive layer CE1b to be a reflector, parts of the third conductive layer CE1c and the fourth conductive layer CE1d that cover the second conductive layer CE1b may be removed or etched to expose an upper surface of the second conductive layer CE1b.

In addition, central portions and edge portions of the third conductive layer CE1c and the fourth conductive layer CE1d, in which the solder pattern SDP is disposed, may remain, and the remaining portions not including the central and edge portions may be removed. In addition, the edge portion of each of the third conductive layer CE1c formed of titanium (Ti) and the fourth conductive layer CE1d formed of indium tin oxide (ITO) may not be etched.

The first conductive layer CE1a and the third conductive layer CE1c may include titanium (Ti) or molybdenum (Mo). The second conductive layer CE1b may include aluminum (Al). In addition, the fourth conductive layer CE1d may include a transparent conductive oxide layer, such as an indium tin oxide (ITO) or indium zinc oxide (IZO) layer, which has high adhesion to the solder pattern SDP, corrosion resistance, and acid resistance. The embodiments of the present specification are not limited thereto.

In addition, the signal line TL, the contact electrode CCE, and the pad electrode PE (see FIG. 8) that are disposed to be coplanar with the first electrode CEL may be formed of multiple layers of conductive materials. The embodiments of the present specification are not limited thereto.

The solder pattern SDP may be disposed on the first electrode CEL disposed below the light-emitting element ED. The solder pattern SDP may bond the light-emitting element ED to the first electrode CEL.

In addition, the contact electrode CCE may be disposed on the second bank BNK-2. The contact electrode CCE may extend to the upper surface and side surfaces of the second bank BNK-2 and may be connected to the pixel driving circuit PD (see FIG. 8) and the pad PE.

The contact electrode CCE may be formed of a plurality of conductive layers. For example, the contact electrode CCE may include the first contact conductive layer CCE-1, the second contact conductive layer CCE-2, and the third contact conductive layer CCE-3, but the embodiments of the present specification are not limited thereto.

For example, each of the first contact conductive layer CCE-1, the second contact conductive layer CCE-2, and the third contact conductive layer CCE-3 may be formed of titanium (Ti), molybdenum (Mo), aluminum (Al), or titanium (Ti), but the embodiments of the present specification are not limited thereto.

To electrically connect the contact electrode CCE to the second electrode CE2, the contact electrode CCE and the second electrode CE2 may be electrically connected through the contact hole 117b-1 formed in the second optical layer 117b disposed on the contact electrode CCE.

However, since there is no transparent conductive layer, such as an ITO layer, which has poor adhesion at the interface with the second optical layer 117, on the third contact conductive layer CCE-3, which is the uppermost layer of the contact electrode CCE on which the second optical layer 117b is disposed, a delamination phenomenon due to poor adhesion at the interface between the second optical layer 117b and the contact electrode CCE does not occur.

In addition, referring to FIG. 13, the insulating layer 116 may be disposed on the second bank BNK-2, the first electrode CEL, and the contact electrode CCE. Specifically, the insulating layer 116 that serves as a passivation layer may be disposed on a plurality of signal lines TL, a plurality of first electrodes CEL, a plurality of contact electrodes CCE, and the fourth organic insulating layer 115d. Since the insulating layer 116 is disposed to cover the remaining areas not including the bending area BA and areas in which the plurality of pads 170 and the solder pattern SDP are disposed, it is possible to reduce the penetration of moisture or impurities into the light-emitting element ED. For example, the insulating layer 116 may be formed of a single layer or multiple layers of silicon oxide (SiOx) or silicon nitride (SiNx) that is an inorganic film material, but the embodiments of the present specification are not limited thereto. For example, the insulating layer 116 may be a protective layer, an insulating layer, etc., but the embodiments of the present specification are not limited thereto.

In addition, the opening 116a may be formed in an area of the insulating layer 116, which is located on the contact electrode CCE on the second bank BNK-2. The width W3 of the opening 116a may be greater than the width W1 of the contact hole 117b-1 formed in the second optical layer 117b. For example, the area of the opening 116a may be greater than the area of the contact hole 117b-1 formed in the second optical layer 117b formed in a subsequent process. Accordingly, since it is not necessary to form a separate opening in the contact electrode CCE located in a formation area of the contact hole for connecting the second electrode CE2 to the contact electrode CCE, it is possible to secure a formation margin of the opening 116a of the insulating layer 116 above the contact electrode CCE, thereby improving misalignment.

Specifically, referring to FIGS. 14 and 15, the width W1 of the short side of the contact hole 117b-1 may be smaller than the width W3 of the short side of the opening 116a formed in the insulating layer 116.

For example, assuming that the width W1 of the short side of the contact hole 117b-1 is 1, the width W3 of the short side of the opening 116a of the insulating layer 116 disposed on the contact electrode CCE may range from about 1.5 to 5.0 and more particularly range from about 2.0 to 4.5. The present embodiment is not limited thereto.

In addition, the width L1 of the long side of the contact hole 117b-1 may be smaller than the width L3 of the long side of the opening 116a of the insulating layer 116 disposed on the contact electrode CCE. For example, assuming that the length L1 of the long side of the contact hole 117b-1 is 1, the length L3 of the long side of the opening 116a of the insulating layer 116 disposed on the contact electrode CCE may range from about 1.1 to 2.0 and more particularly range from about 1.2 to 1.7. The present embodiment is not limited thereto.

In addition, the area of the contact hole 117b-1 may be smaller than the area of the contact opening CCE-4a formed by removing a part of the fourth contact conductive layer CCE-4, which is the uppermost layer of the contact electrode CCE, and the area of the opening 116a of the insulating layer 116 disposed on the contact electrode CCE. For example, assuming that the area of the contact hole 117b-1 is 1, the area of the opening 116a of the insulating layer 116 disposed on the contact electrode CCE may range from about 1.8 to 4.5 and more particularly range from about 1.7 to 3.5. The present embodiment is not limited thereto.

In addition, the opening 116a of the insulating layer 116 may be formed at a location overlapping the contact hole 117b-1 formed in a subsequent process.

The first optical layer 117a may be disposed on the insulating layer 116 covering the plurality of light-emitting elements ED on the second bank BNK-2. For example, the first optical layer 117a may be disposed to cover the plurality of light-emitting elements ED and the second bank BNK-2. For example, the first optical layer 117a may cover spaces between the bank BNK, a part of the insulating layer 116, and the plurality of light-emitting elements ED. For example, the first optical layer 117a may be disposed to surround side portions of the light-emitting element ED and the bank BNK between the insulating layer 116 and the second electrode CE2, but the embodiments of the present specification are not limited thereto. For example, the first optical layer 117a may be a diffusion layer, a sidewall diffusion layer, etc., but the embodiments of the present specification are not limited thereto.

The first optical layer 117a may include an organic insulation material having fine particles dispersed therein, but the embodiments of the present specification are not limited thereto. Light from the plurality of light-emitting elements ED may be scattered by the fine particles dispersed in the first optical layer 117a and emitted to the outside of a display device 1000. Accordingly, the first optical layer 117a can increase the extraction efficiency of the light emitted from the plurality of light-emitting elements ED.

In addition, the second optical layer 117b may be disposed on the insulating layer 116 and the contact opening CCE-4a of the contact electrode CCE. The second optical layer 117b may be in contact with side surfaces of the first optical layer 117a to surround the first optical layer 117a. The second optical layer 117b may be disposed to cover a part of the upper surface and side surfaces of the second bank BNK-2.

In addition, the second optical layer 117b may be formed of the same material as the first optical layer 117a, but the embodiments of the present specification are not limited thereto. For example, the first optical layer 117a may include fine particles, and the second optical layer 117b may not include fine particles.

Here, the contact hole 117b-1 may be formed in an area of the second optical layer 117b, which is located on the second bank BNK-2. The contact hole 117b-1 serves to electrically connect the second electrode CE2 and the contact electrode CCE located below the contact hole 117b-1. In addition, the contact hole 117b-1 may be formed at a location overlapping the opening 116a of the insulating layer 116 disposed on the contact electrode CCE.

Specifically, it is possible to prevent or obviate the delamination phenomenon of the second optical layer 117b by forming the interface between the second optical layer 117b and the contact electrode CCE without a transparent conductive layer. Accordingly, it is possible to expect the crack prevention effect when forming the second electrode CE2, which is a subsequent process. For example, since the second optical layer 117b can be formed on the contact electrode CCE without delamination, the crack problem of the second electrode CE2 due to the deformation of the second optical layer 117b can be prevented or obviated.

In addition, an area of the contact hole 117b-1 in the second optical layer 117b may be smaller than an area of the opening 116a of the insulating layer 116 disposed on the contact electrode CCE.

The second electrode CE2 may be disposed on the first optical layer 117a and the second optical layer 117b. For example, the second electrode CE2 may be electrically connected to the contact electrode CCE through the contact hole 117b-1 of the second optical layer 117b and the opening 116a of the insulating layer 116 under the contact hole 117b-1. It is to be noted that although it is described in the present disclosure that the second electrode CE2 is electrically connected with the contact electrode CCE through a contact hole of the second optical layer 117b, the present disclosure is not limited thereto. For example, a contact hole of the first optical layer 117a may be formed to overlap with the opening 116a of the insulating layer 116, and thus the second electrode CE2 is electrically connected with the contact electrode CCE through the contact hole of the first optical layer 117a.

Accordingly, the second electrode CE2 may be electrically connected to be in direct contact with the contact electrode CCE on which the transparent conductive layer does not exist, thereby preventing or reducing cracks in the second electrode CE2.

In addition, the third optical layer 117c may be disposed on the second electrode CE2 to overlap the plurality of light-emitting elements ED and the first optical layer 117a that are disposed on the second bank BNK-2. Since the third optical layer 117c is disposed above the second electrode CE2 and the plurality of light-emitting elements ED, it is possible to eliminate spots (mura) that may occur in some of the plurality of light-emitting elements ED.

Accordingly, since the light emitted from the plurality of light-emitting elements ED is uniformly diffused by the third optical layer 117c and extracted to the outside of the display device 1000, it is possible to improve the luminance uniformity of the display device 1000.

For example, the third optical layer 117c may be formed of the same material as the first optical layer 117a, but the embodiments of the present specification are not limited thereto.

It is to be noted that although embodiments of the present disclosure are described in a manner that the contact electrode CCE is in contact with the second electrode CE2, the present disclosure is not limited thereto. For example, the contact electrode CCE may be in contact with an intermediate conductive element electrically connecting the contact electrode CCE with the second electrode CE2, rather than the second electrode CE2 itself.

In addition, light from the plurality of light-emitting elements ED may be scattered by the fine particles dispersed in the third optical layer 117c and emitted to the outside of the display device 1000. The third optical layer 117c may uniformly mix the light emitted from the plurality of light-emitting elements ED, thereby further improving the luminance uniformity of the display device 1000. In addition, it is possible to increase the light extraction efficiency of the display device 1000 by the light scattered by the fine particles, thereby enabling low-power driving of the display device 1000. In the display area AA, the black matrix BM may be disposed on the second electrode CE2, the first optical layer 117a, the second optical layer 117b, and the third optical layer 117c. In addition, in the display area AA, the cover layer 118 may be disposed on the black matrix BM.

In this way, according to the present specification, by removing a portion of a transparent conductive layer, which is an uppermost layer of a contact electrode located in a contact hole area, for connecting a second electrode to a contact electrode, or omitting the transparent conductive layer, which is the uppermost layer of the contact electrode, to form an interface between an optical layer and the contact electrode, delamination of the optical layer is suppressed, thereby expecting the crack prevention effect in the second electrode.

According to the present specification, by removing a portion of a transparent conductive layer, which is an uppermost layer of a contact electrode located in a formation area of a contact hole for connecting a second electrode to the contact electrode, to form an contact opening or omitting the transparent conductive layer, which is the uppermost layer of the contact electrode, so as not to form a separate contact opening, it is possible to secure a formation margin of an opening of an insulating layer above the contact electrode, thereby improving misalignment.

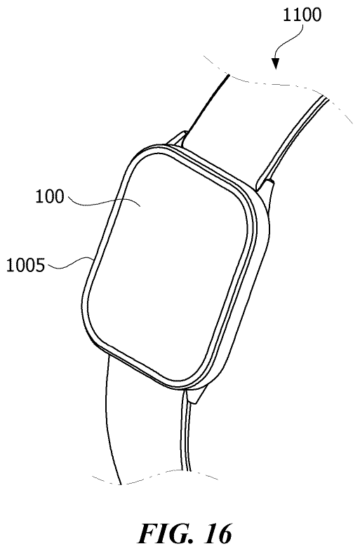

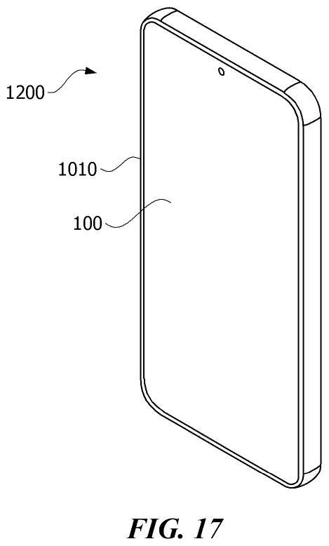

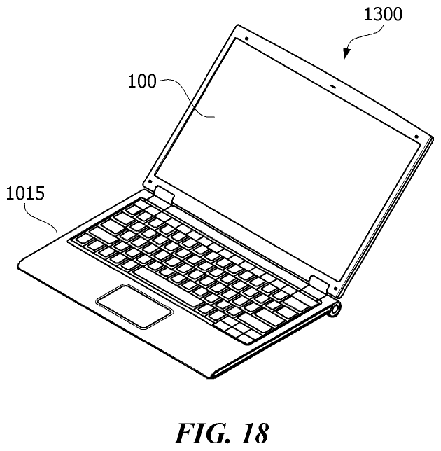

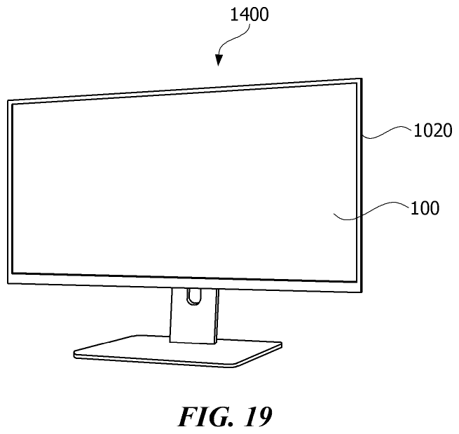

FIGS. 16 to 19 are views illustrating devices to which the display devices according to the embodiments of the present specification are applied.

Referring to FIGS. 16 to 19, the display device 1000 according to embodiments of the present specification may be included in various devices or electronic devices. For example, referring to FIGS. 16 to 19, various electronic devices may include a wearable device 1100, a mobile device 1200, a notebook 1300, and a monitor or TV 1400, but the embodiments of the present specification are not limited thereto.

The wearable device 1100, the mobile device 1200, the notebook 1300, and the monitor or TV 1400 may include case units 1005, 1010, 1015, and 1020, respectively, and the display panel 100 and the display device 1000 according to the embodiments of the present specification, which are described in FIGS. 1 to 15.

The display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present specification may be applied to an organic light emitting lighting device or an inorganic light emitting lighting device.

According to the present specification, by removing an area of a transparent conductive layer, which is an uppermost layer of a contact electrode located in an area of a contact hole for connecting a second electrode to a contact electrode, or omitting the transparent conductive layer, which is the uppermost layer of the contact electrode, to form an interface between an optical layer and the contact electrode, delamination of the optical layer is suppressed, thereby expecting the crack prevention effect in the second electrode.

According to the present specification, by removing an area of a transparent conductive layer, which is an uppermost layer of a contact electrode located in a formation area of a contact hole for connecting a second electrode to the contact electrode, to form an contact opening or omitting the transparent conductive layer, which is the uppermost layer of the contact electrode, so as not to form a separate contact opening, a formation margin of an opening of an insulating layer above the contact electrode is secured, thereby improving misalignment.

Effects of the present specification are not limited to the above-described effects, and other effects that are not mentioned will be able to be clearly understood by those skilled in the art to which the present specification pertains from the following description.

The display device according to various embodiments of the present disclosure may be described as follows.

A display device according to various embodiments of the present disclosure may comprise a plurality of banks disposed on a substrate; a plurality of light-emitting elements disposed on the banks and each connected with a first electrode and a second electrode; a contact electrode disposed to be electrically connected with the second electrode and having a contact opening; and an optical layer covering side surfaces of the plurality of light-emitting elements and the contact electrode and having a contact hole located in the contact opening of the contact electrode, wherein the contact electrode is electrically connected with the second electrode through the contact hole of the optical layer without a transparent conductive layer.

According to one embodiment of the present disclosure, the plurality of banks may include a plurality of first banks and a plurality of second banks that are larger than the plurality of first banks, and the contact electrode is disposed on the second bank.

According to one embodiment of the present disclosure, the contact electrode may include a plurality of conductive layers and a transparent conductive layer, which is an uppermost layer of an area not including an area electrically connected with the second electrode, or includes only the plurality of conductive layers and does not include the transparent conductive layer of the uppermost layer.

According to one embodiment of the present disclosure, the plurality of conductive layers may include a first electrode conductive layer, a reflective conductive layer, and a second electrode conductive layer, and the transparent conductive layer includes indium tin oxide (ITO).

According to one embodiment of the present disclosure, the transparent conductive layer may be not exist in an area of the contact opening of the contact electrode or does not exist in the uppermost layer of the contact electrode.

According to one embodiment of the present disclosure, an uppermost layer among the plurality of conductive layers may be exposed by the contact opening and in contact with the second electrode and/or the optical layer.

According to one embodiment of the present disclosure, the display device may further include an insulating layer disposed between the light-emitting element and the first electrode and between the optical layer and the contact electrode.

According to one embodiment of the present disclosure, the insulating layer may have an opening above the contact opening of the contact electrode.

According to one embodiment of the present disclosure, the opening of the insulating layer may overlap with the contact opening of the contact electrode.

According to one embodiment of the present disclosure, the contact hole of the optical layer may have a smaller area than the contact opening of the contact electrode and the opening of the insulating layer, and the opening of the insulating layer has a greater area than the contact opening of the contact electrode.

According to one embodiment of the present disclosure, an area of the contact is 1.5 to 4 times larger than an area of the contact hole, and an area of the intermediate opening is 1.8 to 4.5 times larger than the area of the contact hole.

According to one embodiment of the present disclosure, the plurality of conductive layers may include a first electrode conductive layer, a reflective conductive layer, and a second electrode conductive layer, and the transparent conductive layer includes indium tin oxide (ITO).

According to one embodiment of the present disclosure, the plurality of conductive layers may include at least one stacked structure of the first electrode conductive layer, the reflective conductive layer, and the second electrode conductive layer.

According to one embodiment of the present disclosure, the optical layer may further include a first optical layer covering side surfaces of the plurality of light-emitting elements; and a second optical layer covering side surfaces of the first optical layer and disposed on the contact electrode.

According to one embodiment of the present disclosure, the display device may further include a third optical layer disposed on the second electrode on the plurality of light-emitting elements.

According to one embodiment of the present disclosure, the display device may further include a black matrix disposed on the second electrode and the third optical layer and having a plurality of transmissive holes; and a cover layer disposed on the black matrix.

According to one embodiment of the present disclosure, the display device may further include a circuit layer between the substrate and the plurality of banks, the circuit layer may further include a pixel driving circuit disposed on the substrate and electrically connected to the plurality of light-emitting elements and the contact electrode; and a plurality of signal lines electrically connecting the first electrode to the pixel driving circuit.

A display device according to various embodiments of the present disclosure may comprise a plurality of banks disposed on a substrate; a plurality of light-emitting elements disposed on the banks and each connected with a first electrode and a second electrode; a contact electrode disposed to be electrically connected with the second electrode and having a contact opening; and an optical layer covering side surfaces of the plurality of light-emitting elements and the contact electrode and having a contact hole located in the contact opening of the contact electrode, wherein the second electrode is electrically connected with the contact electrode through the contact hole of the optical layer, and the contact electrode includes a transparent conductive layer spaced apart from the contact hole.

According to one embodiment of the present disclosure, the contact electrode may include a plurality of conductive layers and a transparent conductive layer, which is an uppermost layer of an area not including an area electrically connected with the second electrode, or includes only the plurality of conductive layers.

According to one embodiment of the present disclosure, the plurality of conductive layers may include a first electrode conductive layer, a reflective conductive layer, and a second electrode conductive layer, and the transparent conductive layer includes indium tin oxide (ITO).

According to one embodiment of the present disclosure, the display device may further include an insulating layer disposed between the light-emitting element and the first electrode and between the optical layer and the contact electrode, wherein an opening is formed in the insulating layer above the contact opening.

According to one embodiment of the present disclosure, the contact hole of the optical layer may have a smaller area than the contact opening of the contact electrode and the opening of the insulating layer, and the opening of the insulating layer has a greater area than the contact opening of the contact electrode.

A display device according to various embodiments of the present disclosure may comprise a plurality of banks disposed on a substrate; a plurality of light-emitting elements disposed on the banks and each connected with a first electrode and a second electrode; a contact electrode disposed to be electrically connected with the second electrode in a contact region; and an optical layer covering side surfaces of the plurality of light-emitting elements and the contact electrode and having a contact hole located in the contact region of the contact electrode, wherein the second electrode is electrically connected with the contact electrode through the contact hole of the optical layer, and wherein an uppermost layer of the contact electrode in contact with the optical layer is not formed of a transparent conductive material.

Although embodiments of the present disclosure have been described in more detail with reference to the accompanying drawings, the present disclosure is not necessarily limited to the embodiments, and various modifications may be carried out without departing from the technical spirit of the present disclosure.

Therefore, the embodiments disclosed in the present disclosure are not intended to limited the technical spirit of the present disclosure, but intended to describe the same, and the scope of the technical concept of the present disclosure is not limited by these embodiments. Therefore, it should be understood that the above-described embodiments are illustrative and not restrictive in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a plurality of banks disposed on a substrate;
a first electrode and a second electrode;
a plurality of light-emitting elements disposed on the banks and each electrically connected with the first electrode and the second electrode;
a contact electrode electrically connected to the second electrode and having a contact opening; and
an optical layer covering side surfaces of the plurality of light-emitting elements and the contact electrode and having a contact hole located in the contact opening of the contact electrode,
wherein the contact electrode is electrically connected with the second electrode through the contact hole of the optical layer without a transparent conductive layer.

2. The display device of claim 1, wherein the plurality of banks includes a plurality of first banks and a plurality of second banks that are larger than the plurality of first banks, and the contact electrode is disposed on the second bank.

3. The display device of claim 1, wherein the contact electrode includes a plurality of conductive layers and a transparent conductive layer, which is an uppermost layer of an area excluding an area electrically connected with the second electrode, or
wherein the contact electrode includes only the plurality of conductive layers and does not include the transparent conductive layer of the uppermost layer.

4. The display device of claim 3, wherein the plurality of conductive layers includes a first electrode conductive layer, a reflective conductive layer, and a second electrode conductive layer, and the transparent conductive layer includes indium tin oxide.

5. The display device of claim 3, wherein the transparent conductive layer does not exist in an area of the contact opening of the contact electrode or does not exist in the uppermost layer of the contact electrode, and an uppermost layer among the plurality of conductive layers is exposed by the contact opening and in contact with the second electrode, the optical layer, or both.

6. The display device of claim 1, further comprising an insulating layer disposed between the light-emitting element and the first electrode and between the optical layer and the contact electrode.

7. The display device of claim 6, wherein the insulating layer has an opening above the contact opening of the contact electrode, and the opening of the insulating layer overlaps with the contact opening of the contact electrode.

8. The display device of claim 7, wherein the contact hole of the optical layer has a smaller area than the contact opening of the contact electrode and the opening of the insulating layer, and the opening of the insulating layer has a greater area than the contact opening of the contact electrode.

9. The display device of claim 8, wherein, an area of the contact is 1.5 to 4 times larger than an area of the contact hole, and an area of an intermediate opening is 1.8 to 4.5 times larger than the area of the contact hole.

10. The display device of claim 9, wherein the plurality of conductive layers includes a first electrode conductive layer, a reflective conductive layer, and a second electrode conductive layer, and the transparent conductive layer includes indium tin oxide.

11. The display device of claim 10, wherein the plurality of conductive layers includes at least one stacked structure of the first electrode conductive layer, the reflective conductive layer, and the second electrode conductive layer.

12. The display device of claim 1, wherein the optical layer further includes:
a first optical layer covering side surfaces of the plurality of light-emitting elements; and
a second optical layer covering side surfaces of the first optical layer and disposed on the contact electrode.

13. The display device of claim 12, further comprising a third optical layer disposed on the second electrode on the plurality of light-emitting elements.

14. The display device of claim 13, further comprising:
a black matrix disposed on the second electrode and the third optical layer, the black matrix having a plurality of transmissive holes; and
a cover layer disposed on the black matrix.

15. The display device of claim 1, further comprising a circuit layer between the substrate and the plurality of banks,
wherein the circuit layer further includes:
a pixel driving circuit disposed on the substrate and electrically connected to the plurality of light-emitting elements and the contact electrode; and
a plurality of signal lines electrically connecting the first electrode to the pixel driving circuit.

16. A display device comprising:
a plurality of banks disposed on a substrate;
a first electrode and a second electrode;
a plurality of light-emitting elements disposed on the banks and each connected with the first electrode and the second electrode;
a contact electrode electrically connected to the second electrode and having a contact opening; and
an optical layer covering side surfaces of the plurality of light-emitting elements and the contact electrode and having a contact hole located in the contact opening of the contact electrode,
wherein the second electrode is electrically connected with the contact electrode through the contact hole of the optical layer, and
wherein the contact electrode includes a transparent conductive layer spaced apart from the contact hole.

17. The display device of claim 16, wherein the contact electrode includes a plurality of conductive layers and a transparent conductive layer, which is an uppermost layer of an area excluding an area electrically connected with the second electrode, or
wherein the contact electrode includes only the plurality of conductive layers.

18. The display device of claim 17, wherein the plurality of conductive layers includes a first electrode conductive layer, a reflective conductive layer, and a second electrode conductive layer, and the transparent conductive layer includes indium tin oxide.

19. The display device of claim 16, further comprising an insulating layer disposed between the light-emitting element and the first electrode and between the optical layer and the contact electrode,
wherein an opening is formed in the insulating layer above the contact opening.

20. The display device of claim 19, wherein the contact hole of the optical layer has a smaller area than the contact opening of the contact electrode and the opening of the insulating layer, and the opening of the insulating layer has a greater area than the contact opening of the contact electrode.
